(19) United States
(12) Patent Application Publication
(10) Pub. No.: US 2005/0195627 A1
(43) Pub. Date: Sep. 8, 2005

(54) High-temperature memory systems

(76) Inventors: Chriswell G. Hutchens, Stillwater, OK (US); Roger L. Schultz, Aubrey, TX (US); Chia-Ming Liu, Stillwater, OK (US); James J. Freeman, Houston, TX (US)

Correspondence Address: Bradley S. Bowling;Baker Botts L.L.P., One Shell Plaza, 910 Louisiana, Houston, TX, 77002-4995, US

(21) Appl. No.: 10/991,705

(22) Filed: Nov. 18, 2004

Related U.S. Application Data
(60) Provisional application No. 60/523,124, filed on Nov. 18, 2003.
(60) Provisional application No. 60/523,122, filed on Nov. 18, 2003.
(60) Provisional application No. 60/523,121, filed on Nov. 18, 2003.

(51) Int. Cl. G11C 19/08

(52) U.S. Cl. 365/7

(57) ABSTRACT

Memory system for storing one or more bits, systems including memory systems, and method for fabricating memory systems are disclosed. The memory system includes a substrate comprising sapphire or diamond, a magnetic random access memory (MRAM) array disposed on the substrate, and a memory controller disposed on the substrate and in communication with the MRAM array.

### CROSS-REFERENCE TO RELATED APPLICATION

This application claims priority to commonly owned U.S. provisional patent application Ser. No. 60/523,124, filed Nov. 18, 2003, entitled “High-Temperature Magnetic Random Access Memory,” by Roger Schultz, Chris Hutchens, James J. Freeman, and Chia Ming Liu. This application claims priority to commonly owned U.S. provisional patent application Ser. No. 60/523,122, filed Nov. 18, 2003, entitled “Cell Library for VHDL Automation,” by Chris Hutchens and Roger Schultz. This application claims priority to commonly owned U.S. provisional patent application Ser. No. 60/523,121, filed Nov. 18, 2003, entitled “SOS Charge Pump,” by Chris Hutchens and Roger L. Schultz.

### BACKGROUND

As activities conducted in high-temperature environments, such as well drilling, becomes increasingly complex, the importance of including electronic circuits for activities conducted in high-temperature environments increases.

Semiconductor based components, including Complementary Metal Oxide Semiconductor (CMOS) devices, may exhibit increased leakage currents at high temperatures. For example, conventional bulk-silicon CMOS devices may exhibit increased leakage currents, and hence decreased resistances, in response to an increase in the environmental temperature of the device.

Many conventional memory devices include one or more semiconductor devices, including random access memory (RAM) and read only memory (ROM). RAM memory devices are typically volatile devices that require periodic refreshing to maintain data stored in the devices. A ROM device, such as an electronically erasable programmable read only memory (EEPROM), typically is a non-volatile device that does not require periodic refreshing to maintain data stored in the device. Both RAM and ROM devices that include semiconductor materials may fail at high temperatures because of increased leakage current in a substrate of the semiconductor material

### BRIEF DESCRIPTION OF THE DRAWINGS

FIGS. 1-16 are diagrams of a memory system.

FIGS. 17-19 are flow charts of a system for fabricating a memory system.

FIGS. 20-25 are diagrams of a transistor in phases of fabrication in an SOS process.

FIGS. 26-33 are I-V curves of leakage current versus drain to source voltage for transistors fabricated using an SOS process.

FIG. 34 is a diagram of an oil-well drilling apparatus.

### DETAILED DESCRIPTION

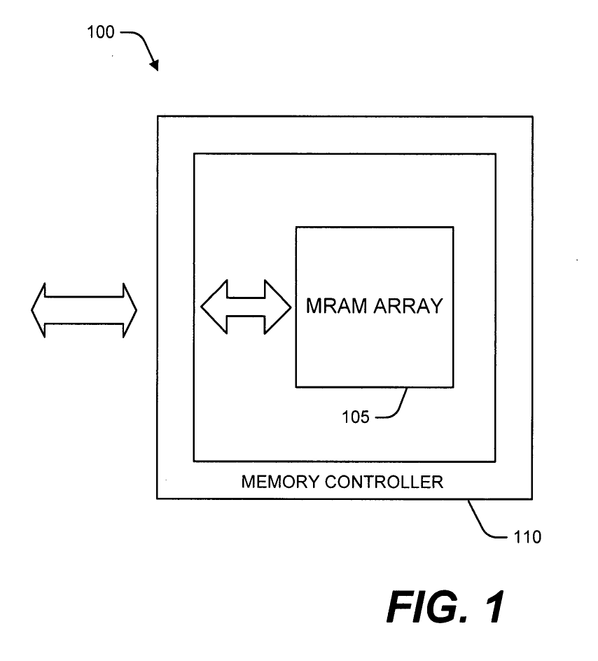

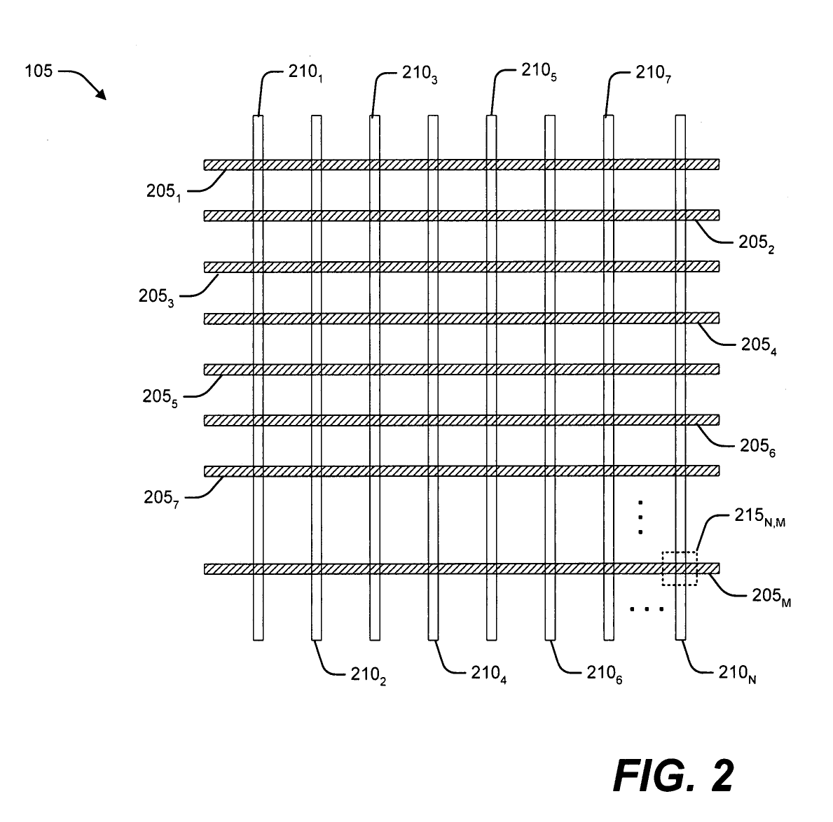

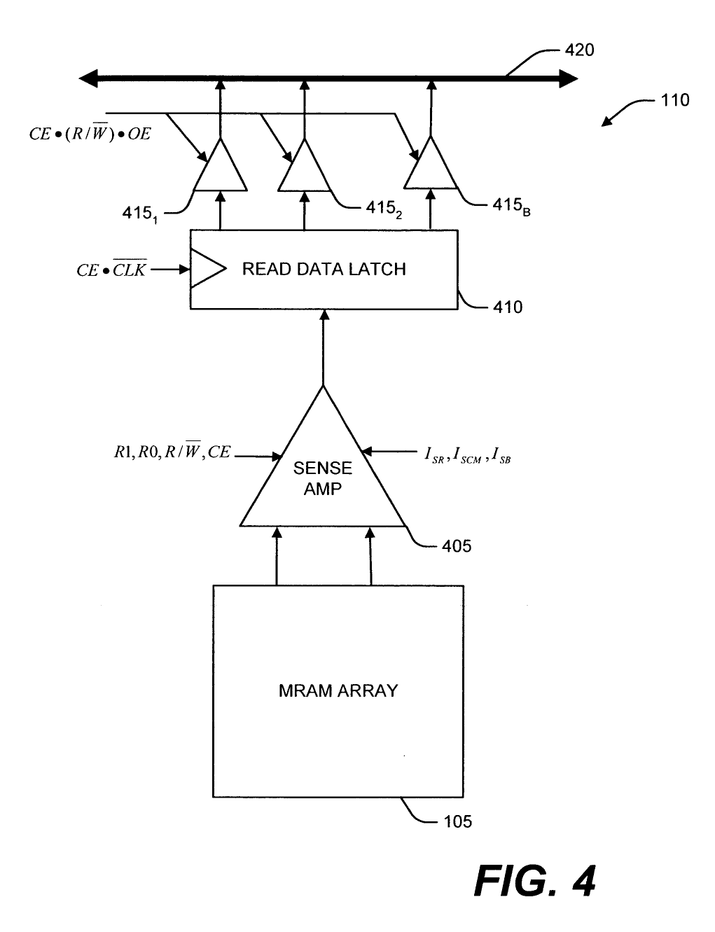

FIG. 1 shows an example memory system 100. The memory system 100 includes a MRAM array 105 (which is shown in greater detail in FIG. 2) to store data. The memory system 100 includes a memory controller 110 (which is shown in greater detail in FIGS. 4-11) in communication with the MRAM array 105. The memory controller 110 includes circuitry to read data from and write data to the MRAM array 105. The memory controller 110 may communicate with other system that may use the memory system 100 to store or retrieve data. The memory system 100 is fabricated on a substrate characterized by a high resistance at an elevated temperature, as discussed below.

Magnetoresistant random access memory (MRAM) is an example memory system. An MRAM system typically includes an MRAM array to store data and control circuitry to read data from and write data to the MRAM array. An MRAM array includes one or more MRAM spots. An MRAM array uses two magnetic fields to store binary information in one or more of the MRAM spots. The state of a spot (e.g., “0” or “1”) depends on whether the two magnetic fields are generally parallel to each other or generally anti-parallel to each other. Spots are generally non-volatile, that is, they do not require periodic refreshing to maintain their stored memory states. Once a spot is set to a magnetized state, the spot generally remains in that magnetized state until a subsequent write operation is performed on the spot. Likewise, reading the state of an MRAM cell generally does not affect the state of the spot. Additionally, spots may function adequately in a high-temperature environment or in a high-radiation environment. A combination of an MRAM array fabricated on semiconductor material suitable for use in a high-temperature environment may produce a high-temperature memory system.

An example MRAM array 105 is shown in FIG. 2. The MRAM array 105 includes one or more word lines 205_{1 . . . M} and one or more sense lines 210, such as sense lines 210_{1 . . . N}. Bits are stored at the intersection of word lines 205, such as sense lines 205_{1 . . . M} and sense lines 210_{1 . . . N}. These intersections may be called spots. An example is spot 215_{N,M}, which is located at the intersection of word line 205_{M} and sense line 210_{N}. The word lines 205_{1 . . . M} and sense lines 210_{1 . . . N} occupy separate physical layers in the MRAM array 105. A magnetic material is placed between the word line 205 and the sense line 210 at each of the cells 215. To store or retrieve bits from the MRAM array 105, signals are applied to word lines 205 and sense lines 210. When signals are applied to an intersecting word line 205 and sense line 210, a bit may be read or written to the spot 215 at the intersection of the word line 205 and sense line 210. The polarity and magnitude of the word line signal and the sense line signal determine whether a bit is read or written to the spot 215. If a bit is to be written to the spot, the magnitude of the word line signal determines whether a “1” or “0” is written to the spot 215. If a bit is to be read from the spot, the voltage drop of the sense line signal over the spot determines whether the spot 215 stores a “1” or “0.”

The word and sense currents may induce a generally parallel magnetic field or a generally anti-parallel magnetic field in the spot 215. The terms parallel and anti-parallel magnetic fields typically refer to the orientation of the magnetic field with respect to the word line 205 traversing the spot 215. For example, a spot 215 with a low resistance (e.g., logic state “1”) may be established by two parallel magnetic fields (e.g., the magnetic field included by the sense signal is generally parallel with the magnetic field induced by the word signal). If the magnetic field in the spot is generally parallel to the word line (i.e., within fifteen degrees of parallel), then it is a generally parallel magnetic field. Otherwise, the magnetic field in the spot is generally anti-parallel.

The spot 215 will have a low resistance to the sense signal traversing the spot 215 when the magnetic field generated by the word line 205 traversing the spot 215 is generally parallel to the established magnetic field generated by the sense signal. This state represents the spot 215 storing a logic high values (i.e., “1”). The spot 215 will have a high resistance to the sense signal when the magnetic field generated by the word line 205 traversing the spot 215 is generally anti-parallel to the magnetic field generated by the sense signal. This state represents the spot 215 storing a logic low value (i.e., “0”).

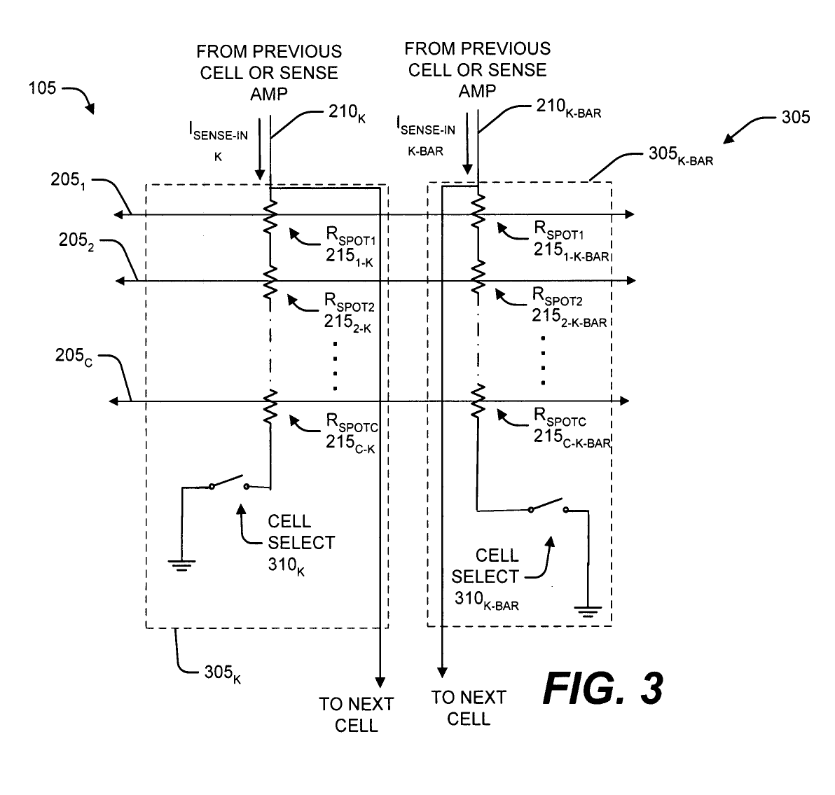

Although each of the spots 215 may exhibit a change in resistance, one or more of the spots 215 may be grouped together to increase the change in resistance between logic states. For example, FIG. 3 shows an example of two groups of spots in MRAM array 105, represented as resistances. Spots R_{SPOT1} 215_{1-K}, R_{SPOT2} 215_{2-K}, and R_{SPOTC} 215_{C-K}, are a selection of the spots traversed by sense line 210_{K} that form a cell 305_{K}. An example memory system 100 may group these spots as a single logic unit. For example, one or more of the spots in cell 305_{K} may be set to the same logic state. The drop in voltage across this group of spots may be measured across the cell as a group. Certain example memory systems 100 may include a cell select switch 310_{K}, to select the cell for reading or writing.

The example memory system may also include a selection of spots R_{SPOT1} 215_{1-K-BAR}, R_{SPOT2} 215_{2-K-BAR}, and R_{SPOTC} 215_{C-K-BAR}, along sense line 210_{K-BAR} that form a cell 305_{K-BAR}. Cell 305_{K-BAR} may include a cell select switch 310_{K-BAR} for selecting cell 305_{K-BAR} for reading or writing. In some example systems, one or more of the cell select switches 305_{K} or 305_{K-BAR} may be located in the memory controller 110. In one example memory system 100, cells 305_{K-BAR} and 305_{K-BAR} may be used as a signal memory unit to store a bit. For example, the memory system 100 may store a logic state of a bit in cell 305_{K} and the inverse of the logic state of the bit in cell 305_{K-BAR}. The example memory system 100 may determine the logic state of this combined cell 305 by determining the difference in the current flowing in cell 305_{K} and the current flowing in cell 305_{K-BAR}. Other example systems may measure a differential in the voltage drops of cell 305_{K} and cell 305_{K-BAR}.

The sizing and layout of the cells in the MRAM array 105 may be adjusted based on the needs of the system. In some example systems, the cells in the MRAM array may be adjusted so that the word and sense lines have generally equal impedances. In other example system, the cells in the MRAM array may be adjusted so that the time for a signal to traverse one or more word lines and one or more sense lines is approximately equal.

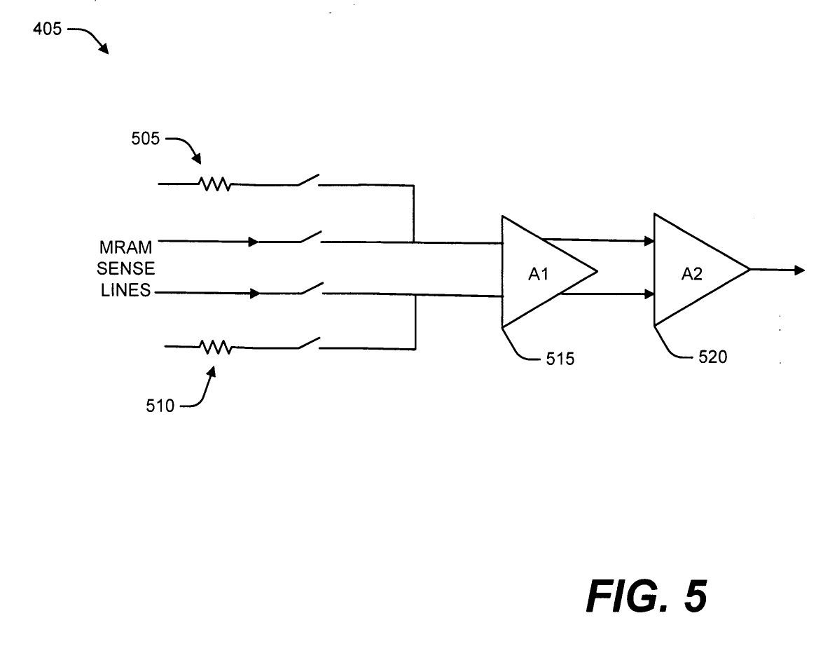

An example portion of the memory controller 110 for reading one or more bits from the MRAM array 105 is shown in FIG. 4. The example system includes a sense amplifier 405 (which is shown in greater detail in FIG. 5). The sense amplifier 405 may receive one or more signals from the MRAM array. The sense amplifier 405 may receive one or more control signals such as read bits R0 and R1, read/write select R/\overline{W}, or chip enable CE. The sense amplifier 405 may also receive one or more reference currents such as the sense read current I_{SR}, the common mode sense current I_{SCM}, or the sense bias current I_{SB}. In some example system, the sense amplifier 405 may apply one or more of these currents to the one or more sense lines 210_{1 . . . N} of the MRAM array 105.

The memory controller 110 may include one or more read data latches 410 for storing data from the MRAM array 105. The one or more read data latches 410 may be latched on a clock signal or another signal such as chip enable ANDed with an inverted clock signal (CE•CLK). The memory controller may include one or more buffers 415_{1 . . . B}. The one or more buffers 415_{1 . . . B} may be activated by a signal such as the chip enable signal ANDed with the read/write signal ANDed with the output enable signal (CE•(R/\overline{W})•OE) In one example memory controller 110 a high read/write signal indicates a read. In another memory controller 100 a high read/write signal indicates a write. The memory controller 110 may include a bus 420 for outputting the one or more bits read from the MRAM array 105. In one example system, a sense current of 10 mA is applied to a sense line to be read.

An example sense amplifier 405 for reading one or more bits from the MRAM array 105 is shown in FIG. 5. The sense amplifier 405 may include one or more resistors, such as 505 or 510 to switch into a differential amplifier 515. The sense amplifier 405 is designed to read a bit from a cell where the cell has a K cell 305_{K} and a K-bar cell 305_{K-BAR}. In such a situation, the switches connecting the amplifier 515 to the sense lines to be read (e.g., 210_{K} and 210_{K-BAR}) are closed and the switches to the resistors 505 and 510 are opened.

Once the input to the sense amplifier 405 is selected, the differential amplifier 515 amplifies the difference in the two inputs by a factor of A1. In one example system the gain A1 approximated by the following equation:

$$A1 = \frac{{μ}^{3} \cdot {g}_{m} \cdot R \cdot I}{2}$$

where μ is the self gain of the amplifier, gₘ is the transconductance of the amplifier, R is the resistance of the load, and I is the current into the amplifier. In one implementation μ may be about 30, gₘ may be about 10 mS, R may be about 1 KO, and I may be about 2 mA. The amplifier 515 may produce one or more outputs. The one or more outputs of the amplifier 515 may be input into a second differential amplifier 520 which may apply a gain of A2 to the input from amplifier 515. In one example system, the gain A2 may be approximated by the following equation:

$$A2 = \frac{2 \cdot {V}_{AN} \cdot {V}_{AP}}{Δ V ( {V}_{AN} + {V}_{AP} )}$$

where ΔV is the overdrive voltage of the amplifier 520, V_{AN} is the Early voltage of one or more of the N-channel transistors in the amplifier 520 and V_{AP} is Early voltage of one or more of the P-channel transistors in the amplifier 520. In one example implementations, V_{AN} may be between 2 V and 40 V and V_{AP} may be between 2 V and 40 V. The end result of the amplification by the two differential amplifiers 515 and 520 is that the output of the amplifier 520 will be near one side of the power supply rail when the cells being read are in one logic state and near the other power supply rail when the cells being read are in the other logic state.

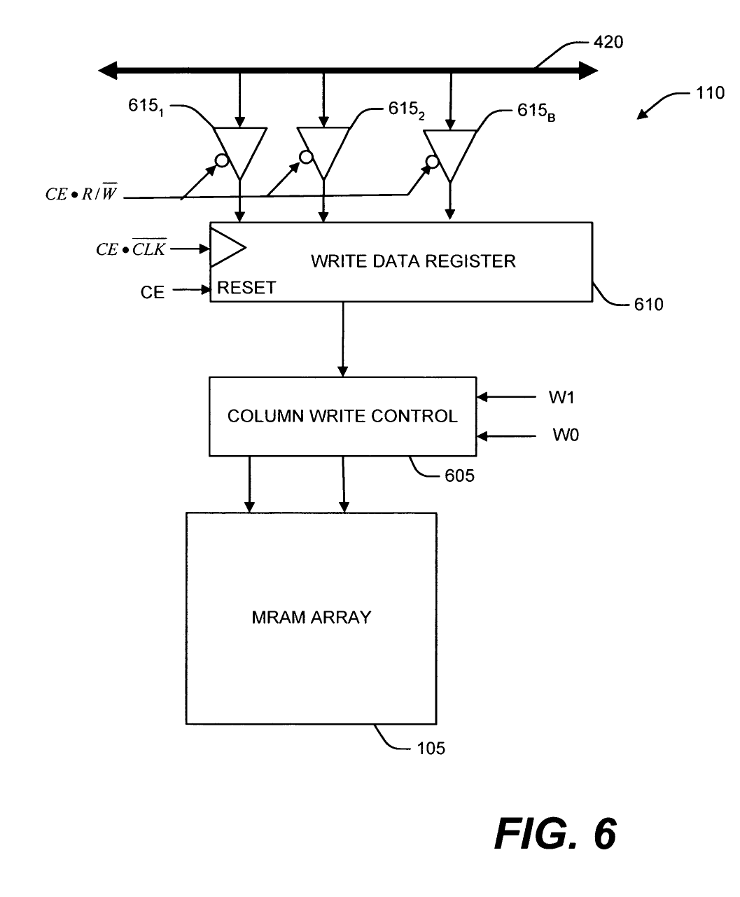

An example portion of the memory controller 110 for writing one or more bits to the MRAM array 105 is shown in FIG. 6. The memory controller 110 may include column write controller 605 to control which one or more columns receive sense currents for writing. The column write controller 605 may receive one or more control signals such as W0 or W1 write bits, which may control the timing of when the one or more bits are written to the MRAM array 105. The column write controller 605 may receive one or more data bits for writing from one or more write data registers 610. The write data register 610 may store data bits for writing. The write data register 610 may be clocked on a signal such as chip enable ANDed with the inverted clock signal (CE•CLK). The write data register 610 may also include a reset line to reset the values stored in the write data register 610. The reset line may be activated by an edge of the chip enable (CE) signal.

The write data register 610 may receive one or more data bits from one or more write buffers 615_{1 . . .B}, which may be activated by a signal such as the chip enable ANDed with the read/write signal (CE•(R/\overline{W})). The buffers 615_{1 . . . B} may receive one or more data bits from the data bus 420.

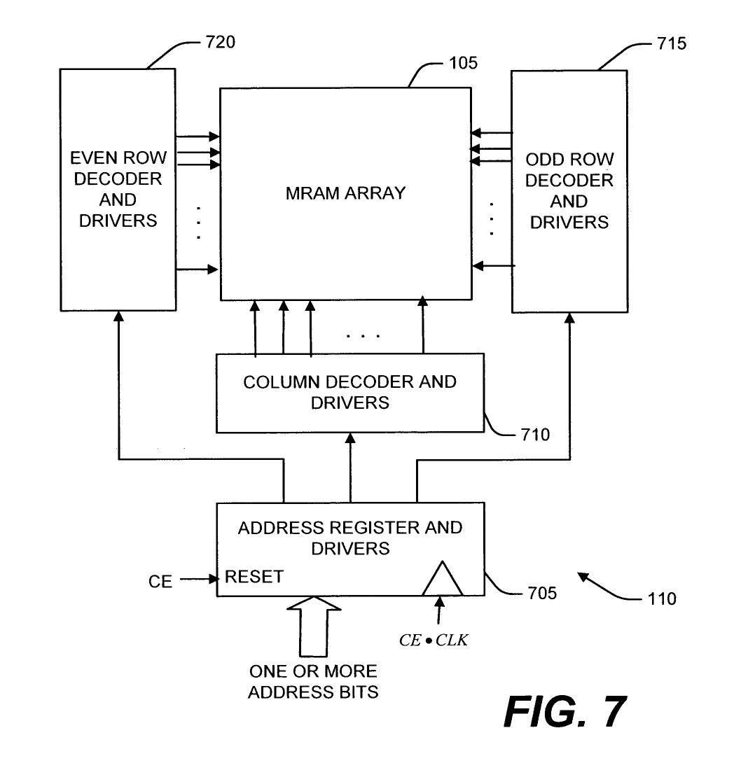

An example portion of the memory controller 110 for addressing one or more cells 305 in the MRAM array 105 is shown in FIG. 7. The memory controller 110 may receive one or more address bits, which are applied to the address registers and drivers 705. The address registers and drivers 705 may store the one or more address bits until clocked by a signal, such as the chip select signal ANDed with the clock signal (CE•CLK). The address registers and drivers 705 may include a reset line to clear the contents of the address registers 705. The resent line my be activated by a signal, such as the rising edge of the chip enable (CE) signal.

The address registers and drivers 705 may send one or more of the address bits to the column decoders and drivers 710 (which are shown in greater detail in FIG. 8) and one or more row decoders and drivers, such as odd row decoder and drivers 715, or even row decoder and drivers 720. Other example systems may not have the row decoder and drivers split on odd or even rows. The column decoder and driver 710 and row decoders and drivers 715 and 720 co-operatively select one or more cells 305 in the MRAM array 105, as described above.

An example column decoder and driver 710 is shown in FIG. 8. The column decoder 805 receives one or more bits from the address registers and driver 705. Based on the one or more bits received, it selects one or more columns (e.g., sense lines 210_{1 . . . N}) in the MRAM array 210 and activates one or more column drivers 810_{1 . . . N} to apply a sense signal to the one or more selected sense lines 210_{1 . . . N}.

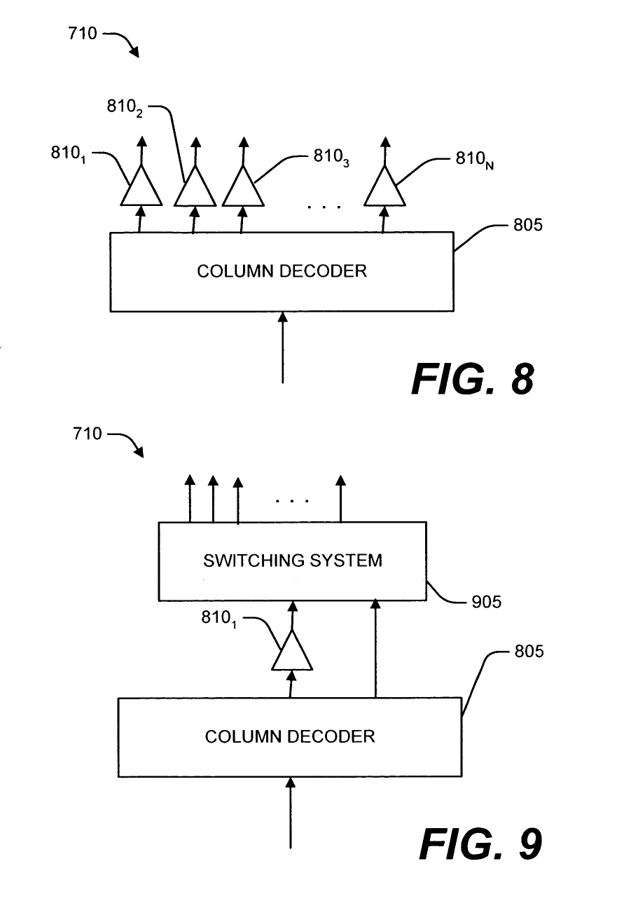

The example column decoder and driver system 710 shown in FIG. 9 includes only one column driver 810₁. The current from the column driver 810₁ is switched to one or more sense lines 210_{1 . . . N} by the switching system 905, as determined by the bits from the address registers and driver 705.

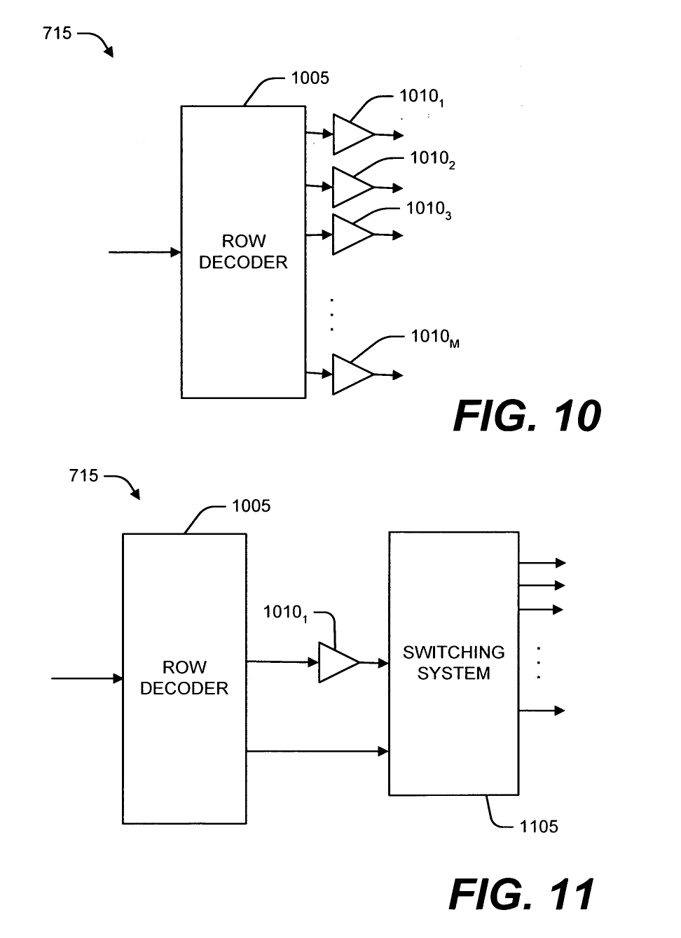

An example row decoder and driver system 715 is shown in FIG. 10. The row decoder 715 receives one or more bits from the address registers and driver 705. Based on the one or more bits received, it selects one or more rows (e.g., word lines 215_{1 . . . M}) in the MRAM array 210 and activates one or more of the row driver 1010_{1 . . . M} to apply a word signal to the one or more selected word lines 215_{1 . . . M}.

The example row decoder and driver system 715 shown in FIG. 11 includes only one word driver 1010₁. The current from the word driver 1010₁ is switched to one or more word lines 215_{1 . . . M} by the switching system 1105.

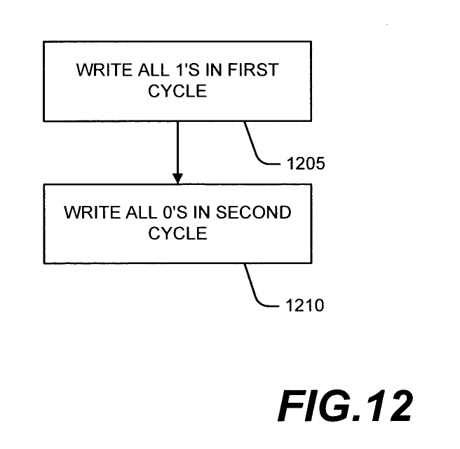

An example method of operating a row decoder and drivers 715, such as the one shown in FIG. 11 is shown in FIG. 12. The row driver 1010₁ may only produce a signal current at any time. In such a system, the memory controller 110 may write all “1's” in a first cycle (block 1205) and write all “0's” in a second cycle (block 1210). This method of writing bits cyclically rather than using multiple row driver 1010_{1 . . . M} may be a viable trade-off of speed for space savings and less energy.

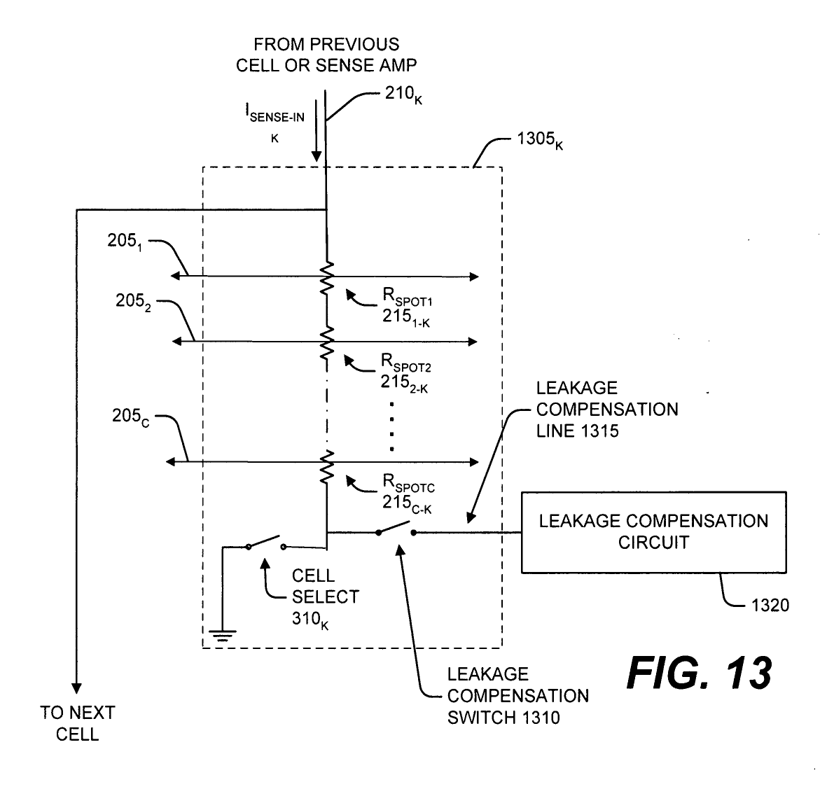

FIG. 13 shows an example cell 1305_{K} that includes a leakage compensation switch 1310 to short the cell to a leakage compensation circuit 1320 thorough the leakage compensation line 1315. In general, the memory system 100 may include one or more leakage compensation circuits to compensate for leakage current in the MRAM array 105 or the memory controller 110. In operation, the leakage compensation circuit 1320 is attached to each cell on a sense line 210_{K} that is not being read from or written to in a present cycle.

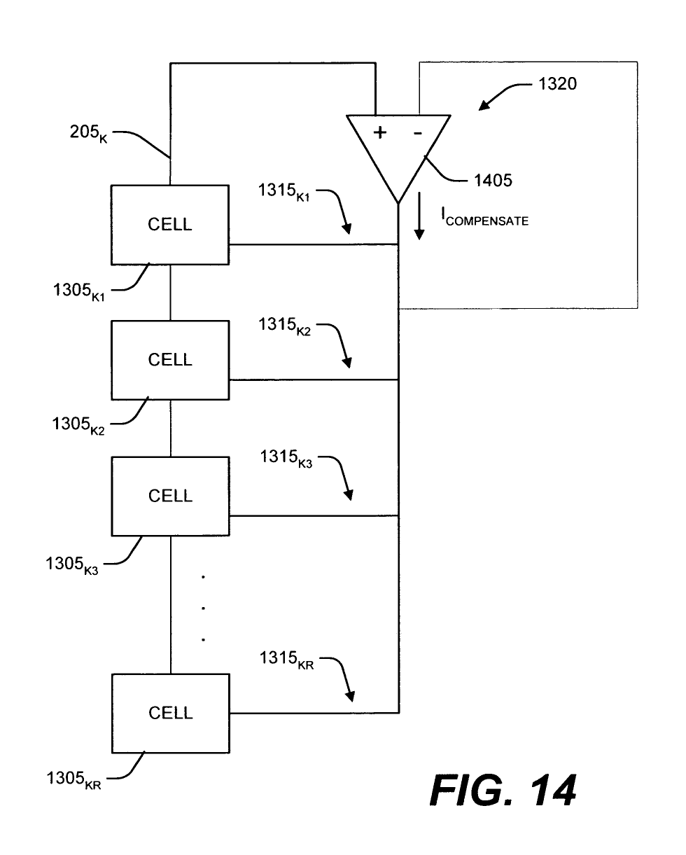

An example leakage compensation circuit 1320 is shown in FIG. 14. Each of the one or more cells 1305_{K1 . . . KR} on sense line 205_{K} that are not being read from or written to in a cycle are shorted to the leakage compensation circuit 1320 though their leakage compensation line 1315_{K1 . . . R}. The leakage compensation circuit include a buffer 1405 with a gain. In one example system the gain of the buffer is one (unity). In example system with K and K-bar banks of cells, there is a separate buffer 1405 for the K cells and the K-bar cells.

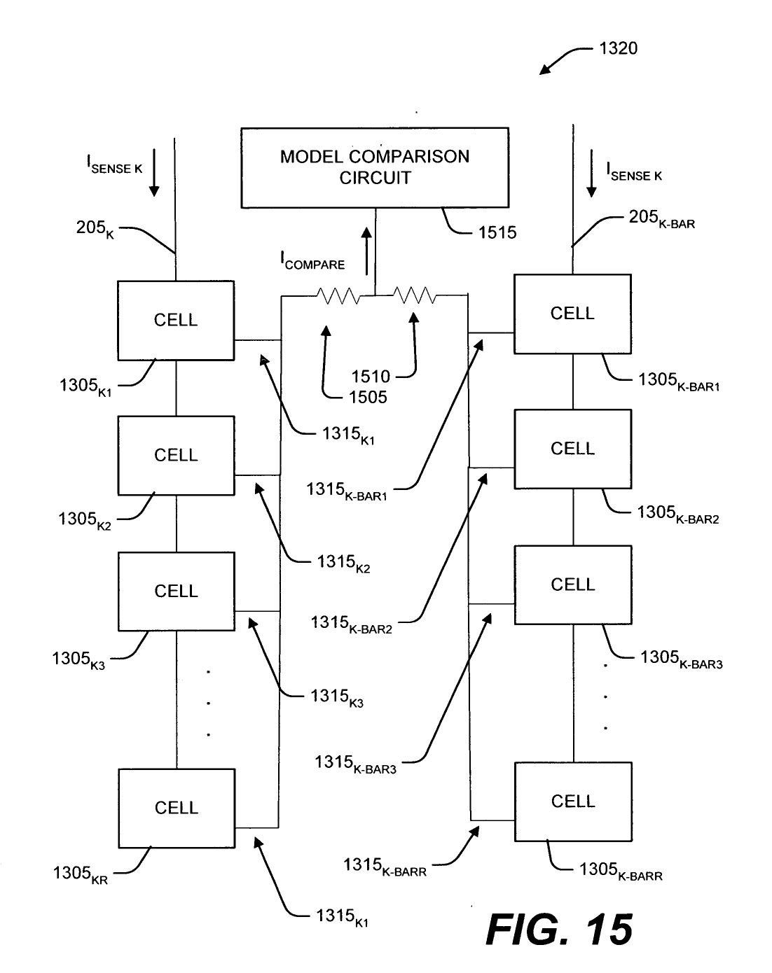

Another example leakage compensation circuit 1320 is shown in FIG. 15. Each of the cells on the sense line 205_{K} and sense line 205_{K-BAR} that are not being read from or written to in a cycle are shorted to a model comparison circuit 1515 though resistors 1505 and 1510, respectively. In some example systems, the resistors 1505 and 1510 have a high resistance (e.g., 1 KO).

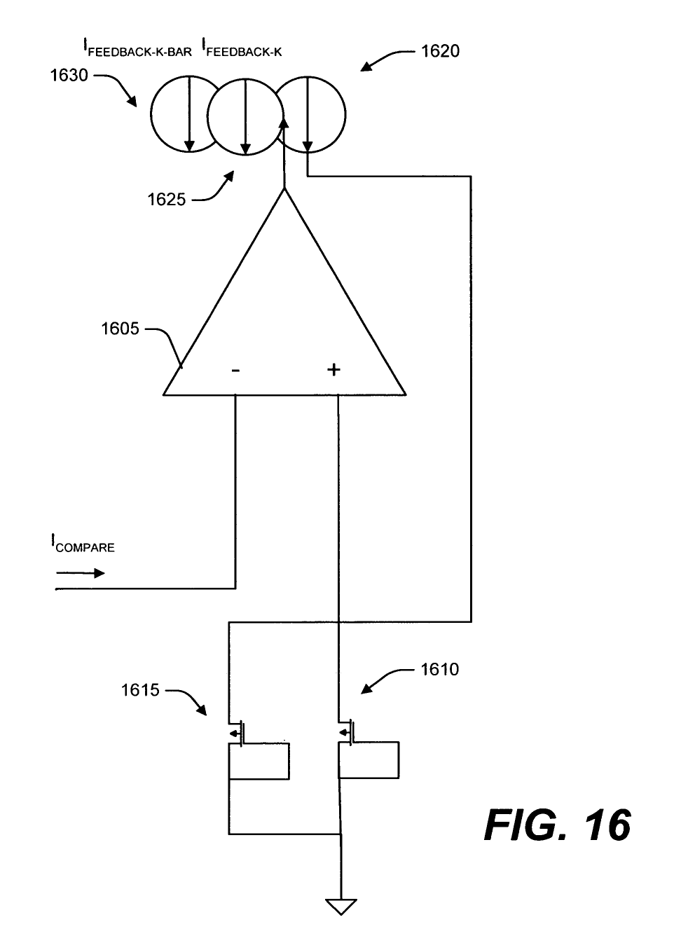

FIG. 16 shows an example model comparison circuit 1515. The model comparison circuit 1515 may include an amplifier 1605 with an inverting input and a non-inverting input. The model comparison circuit may also include one or more transistors, such as transistors 1610 and 1615. The model comparison circuit may include a current mirror with elements 1620, 1625, and 1630.

The amplifier 1605 may compare the comparison signal from the cells (I_{COMPARE}) with the signal from a model circuit that may include transistors 1610 and 1615. The transistors 1610 and 1615 may model a set of cells, like cells 1305K_{1 . . . R} and 1305_{K-BAR1 . . . R}, when one cell in each bank is selected for reading or writing. For example the transistor 1610 may have an impedance that is approximately equal to (m−1) cells in parallel. In one example system, the transistor 1610 may have an impedance that models (m−1) 200 O resistors. In some example systems the resistance of the transistor 1610 may be scaled by c. The transistor 1615 may have a minimum geometry. For example the active layer of the transistor 1615 may have a channel region with a length Lₘᵢₙ and a width Wₘᵢₙ. The transistor 1615 may function as a current mirror to the current through transistor 1610.

The output of the amplifier 1605 may be fed though a current mirror with elements 1620, 1625, and 1630. The output of the current mirror element 1620 may be fed back into transistors 1610 and 1615. The other current mirror elements 1625 and 1630 may feed their mirrored currents back into the sense line for K and K-bar, respectively. In certain implementations, where the resistance of the cells is scaled by c, as discussed above, the ratio of the current in the current mirror elements 1620, 1625, and 1630 may be approximately equal to 1:c:c, respectively. The scaling factor “c” may be a geometric ratio to control the desired current ratio.

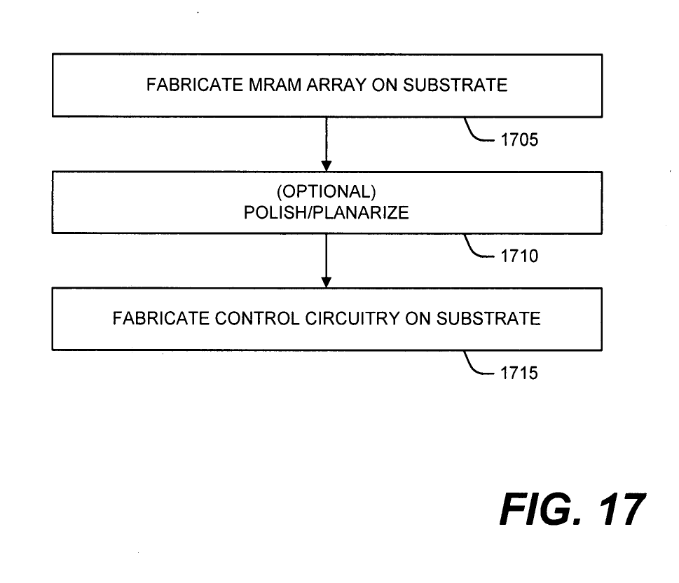

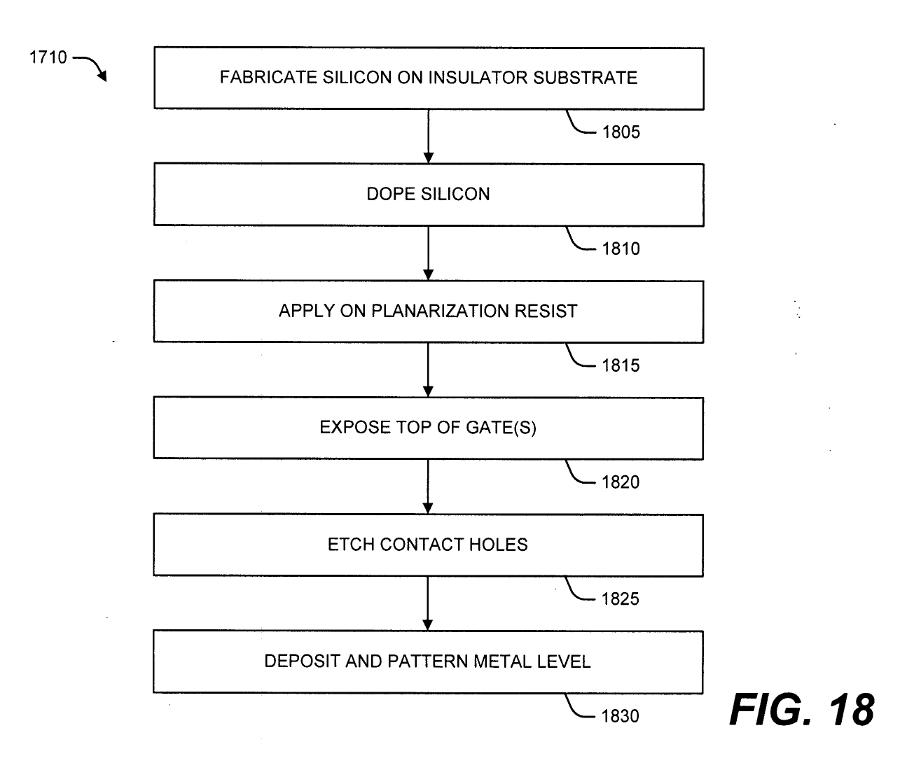

FIG. 17 shows an example system for fabricating a memory system 100 on an insulator substrate. The MRAM array 105 is fabricated on the substrate (block 1705). The MRAM array 105 and the substrate are optionally polished or planarized (block 1710). In some example implementations, the polishing or planarization is accomplished using a Chemical Machine Polishing (CMP) system. The memory controller 110 is fabricated on the substrate (block 1715, which is described in greater detail with respect to FIG. 18). In certain example systems the order of blocks 1705-1715 may be changed.

An example system for fabricating a circuit, such as memory controller 110, on an insulator substrate is shown in FIG. 18. Although the example system shown in FIG. 18 is for fabricating a transistor it may be generalized to fabricate other devices on the substrate. The system fabricates a active layer on the insulator substrate (block 1805). The system dopes the silicon to create one or more p regions and one or more n regions (block 1810). The system may apply a planarization resist to one or more portion of the device (block 1815). The system may planarize the device to expose the top of one or more gates in the device (block 1820). The system may etch more or more contact holes to connect one or more portions of the device to a metal layer (block 1825). The system may deposit and pattern the metal layer (block 1830).

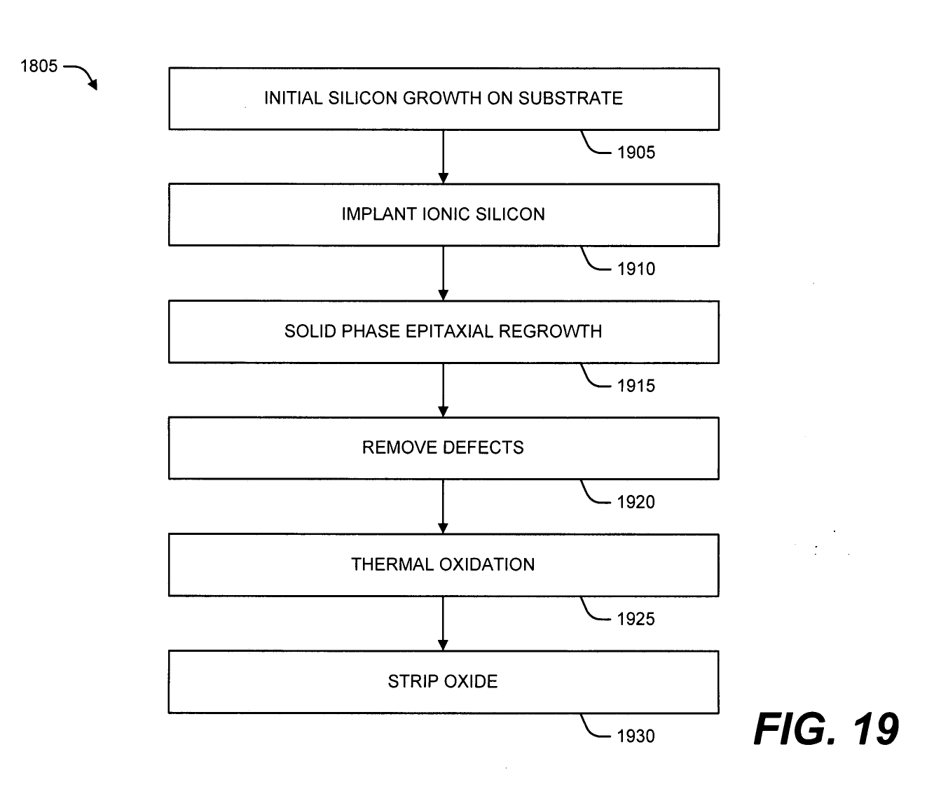

An example system for fabricating a active layer on an insulator substrate (block 1805) is shown in FIG. 19. The example system shown in FIG. 19 creates a thin-film layer of silicon on the insulator substrate. The system performs an initial silicon grown on the substrate (block 1905). This initial growth may be performed by chemical vapor deposition. The system implants an ionic active layer (e.g., positively charged) on the initial active layer (block 1910). The system may anneal the active layer by facilitating a solid phase epitaxial regrowth (block 1915). This process may be performed at an elevated temperature, for example at a temperature of about 550° C. The system may also anneal the active layer by removing defects (block 1920). This removal of defects may also be perfumed at an elevated temperature, for example at a temperature of about 900° C. The system may cause the active layer to undergo thermal oxidation to form an oxide layer (e.g., SiO₂) on the active layer (block 1925). The system may then strip the oxide layer from the silicon layer. The system may then strip the oxide layer from the active layer (block 1930).

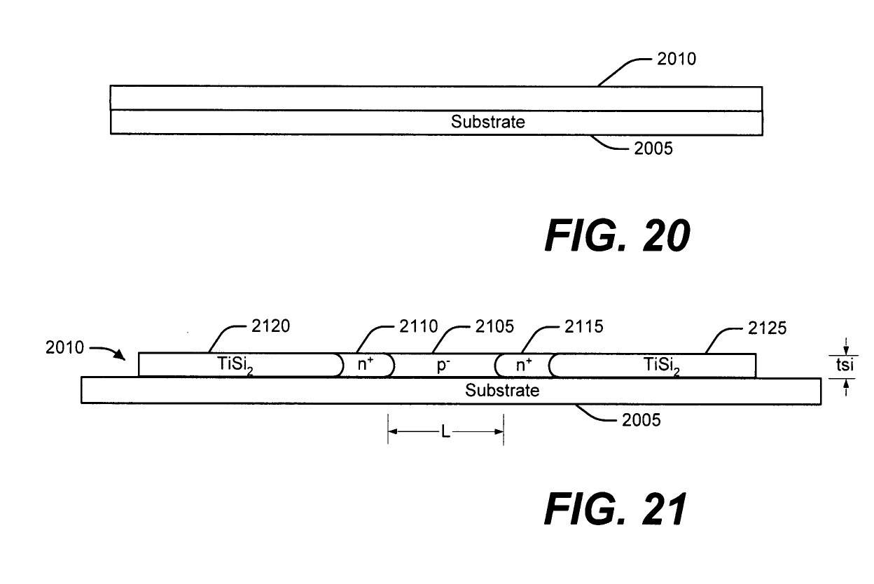

FIGS. 20-25 show an example device (e.g., an NMOS transistor) in phases of fabrication according to the system shown in FIG. 17. Although an NMOS transistor is illustrated in FIG. 20-25, in general other semiconductor devices may be fabricated according to the system shown in FIG. 17. FIG. 20 shows the example device after the active layer 2010 is fabricated on the insulator substrate 2005. The insulator substrate 2005 may be any material that exhibits a high resistance at an elevated temperature. Example substrates may include diamond and sapphire. Because of the high resistance of the insulator substrate 2005 at elevated temperatures, devices fabricated on the insulator substrate 2005 may exhibit lower leakage currents at elevated temperatures than devices fabricated on substrates with low resistance at elevated temperatures.

FIG. 21 shows the example device after one or more regions of the active layer 2010 are doped (FIG. 17, block 1710). The active layer 2010 may include one or more p-regions, such as p-region 2105. The p− region 2105 may be the channel region of the active layer 2010. The active layer 2010 may include one or more n regions, such as n+ regions 2110 and 2115. The n+ regions 2110 and 2115 may be the drain and source regions of the active layer. The active layer may include one or more silicide regions such as TiSi₂ regions 2120 and 2125. The active layer may be etched away outside the silicide regions 2120 and 2125.

FIG. 21 also illustrates the dimensions of the device. The active layer 2010 has a thickness tSi. The channel region of the active layer 2010 has a length L. The active layer 2010 and the substrate 2005 also include a width which is in the dimension into and out of the figure.

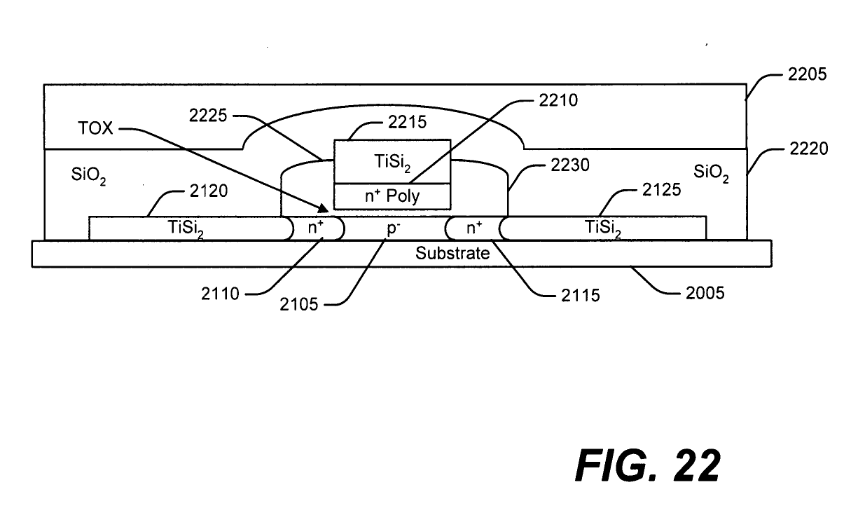

FIG. 22 shows the example device after additional semiconductor layers are formed and a planarization resist is applied to the device (FIG. 17, block 1715). One or more poly layers such as the n-poly layer 2210 may be fabricated on the device. The poly region 2210 may be separated from the active layer 2010 by a thickness TOX. One or more silicide layers, such as TiSi₂ layer 2215 may be fabricated on the device. An oxide layer, such as SiO₂ layer 2220 may be applied to the device. The SiO₂ layer 2220 may include one or more sidewalls such as SiO₂ sidewalls 2225 and 2230. A planarization resist 2205 may be spun onto the device.

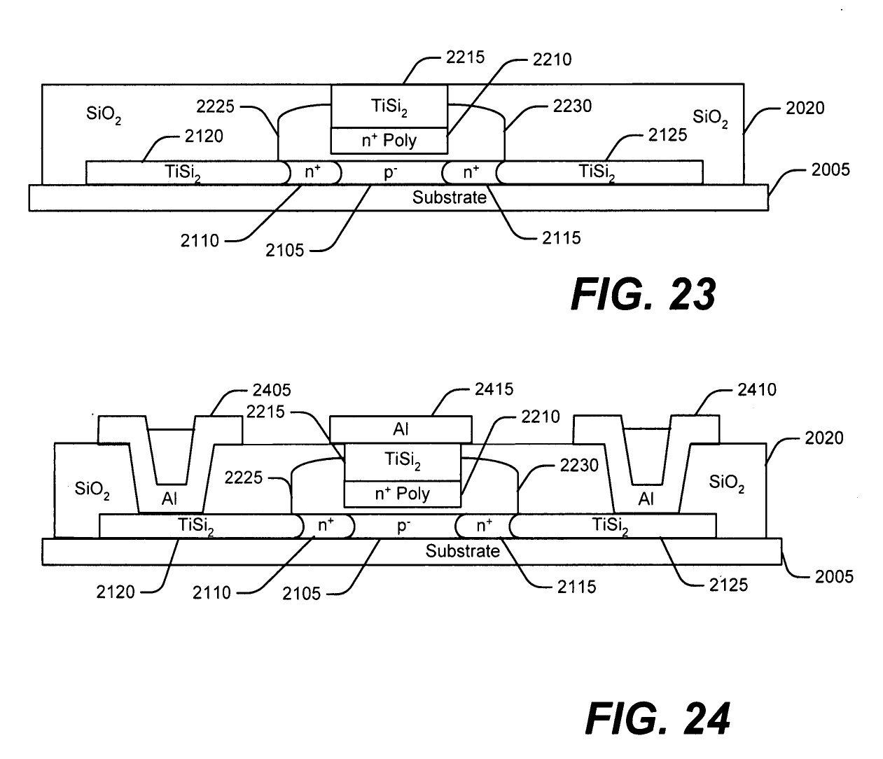

FIG. 23 shows the example device after planarization (FIG. 17, block 1720). The planarization may expose one or more gates, such as the top of TiSi₂ layer 2215. FIG. 24 shows the example device after one or more contact holes are etched (block 1725) and a metal layer is deposited and patterned (block 1730). In the example system, contact holes 2405 and 2415 may be etched so that metal layers 2405 and 2410 may contact TiSi₂ regions 2120 and 2125, respectively. A metal layer 2415 may also be deposited and patterned to contact TiSi₂ layer 2215. The metal layers may include one or more conductive materials. For example the metal layers 2405, 2410, and 2415 may include aluminum.

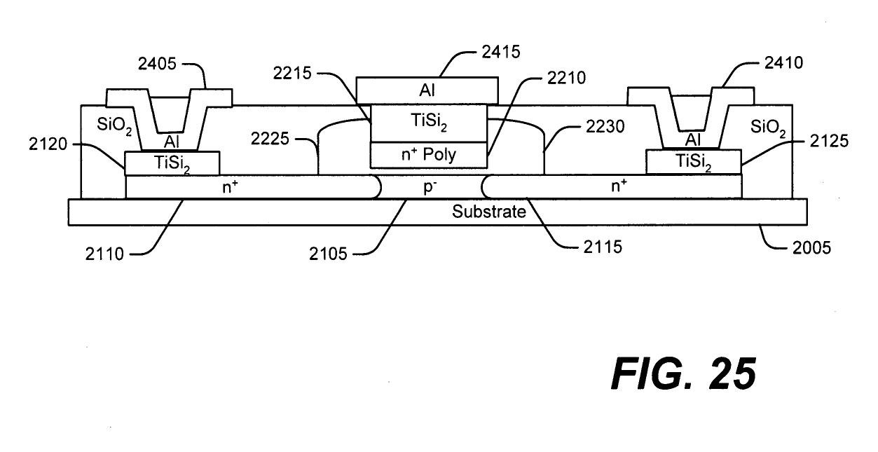

FIG. 25 shows another example semiconductor device. The silicide regions of the active layer (TiSi₂ regions 2120 and 2125) may silicide layers that are disposed on, or partially within, the active layer 2010.

Temperature-dependent effects of semiconductor materials may affect the operation of the electronic circuitry disposed on the semiconductor material. For example, a change in temperature may decrease the electron/hole mobility or threshold voltage of the electronic circuitry, which may increase the leakage current of the semiconductor material. In general, the leakage current of a semiconductor material increases with temperature. A change in the leakage current may, in turn, affect the performance of the electronic circuitry. In certain situations, when the leakage current of the electronic circuitry exceeds a threshold value, the electronic circuitry may loose its semiconductor properties and function as a low resistance device. This may result in a failed read or write of an MRAM cell 215.

The temperature-dependant properties and structure of MRAM cells may affect the design of the memory controller 110. Suitable high temperature control circuitry for an MRAM array may include electronic circuitry fabricated from semiconductor materials that exhibit low leakage currents at elevated temperatures. Example fabrication processes include SOI, SOS, and SOD.

The leakage current of a semiconductor device may be a function of the device's physical dimensions or geometry, the temperature of the device, and one or more signals applied to the device. The physical dimensions of the device may include the width, length, and thickness of the one or more features of the device, such as the substrate, one or more regions of the active layer, and the TOX of the transistor.

One or more of these dimensions may be altered to achieve a desired behavior from the device. For example in one example device the ratio of tSi/L may be greater than 3. In other example implementations, the ratio tSi/L may be greater than 5 or 7. In other example implementations, the ratio tSi/L may be between 7 and 30. In other example implementations, the ratio tSi/L may be between 11.8 and 25. In other example implementations the ratio tSi/L may be about 17.7.

In another example device, the dimensions may be chosen so that, for one more transistors, a ratio I_{ON}/I_{OFF} is greater than a predetermined ratio at a predetermined temperature. I_{OFF} is a leakage current that flows thorough the substrate (e.g., substrate 2005) of a transistor when the device is not active (i.e. “off”). I_{ON} is a drive current that flows between the drain and the source, though the channel region of the transistor, when the semiconductor device is active (i.e. “on”). In one example system the dimensions of one or more transistors are adjusted so that the I_{ON}/I_{OFF} is greater than 10,000, for temperatures up to 300° C. In another example system, the dimensions of one or more transistors are adjusted so that I_{ON}/I_{OFF} is greater than 10,000, for temperatures up to 240° C. I_{ON}/I_{OFF} is greater than 10,000, for temperatures up to 125° C. In one example system the dimensions of one or more transistors are adjusted so that the I_{ON}/I_{OFF} is greater than 1,000, for temperatures up to 300° C. In another example system, the dimensions of one or more transistors are adjusted so that I_{ON}/I_{OFF} is greater than 1,000, for temperatures up to 240° C. I_{ON}/I_{OFF} is greater than 1000, for temperatures up to 125° C. In one example system the dimensions of one or more transistors are adjusted so that the I_{ON}/I_{OFF} is greater than 1000, for temperatures up to 300° C. In another example system, the dimensions of one or more transistors are adjusted so that I_{ON}/I_{OFF} is greater than 1000, for temperatures up to 240° C. I_{ON}/I_{OFF} is greater than 1000, for temperatures up to 125° C.

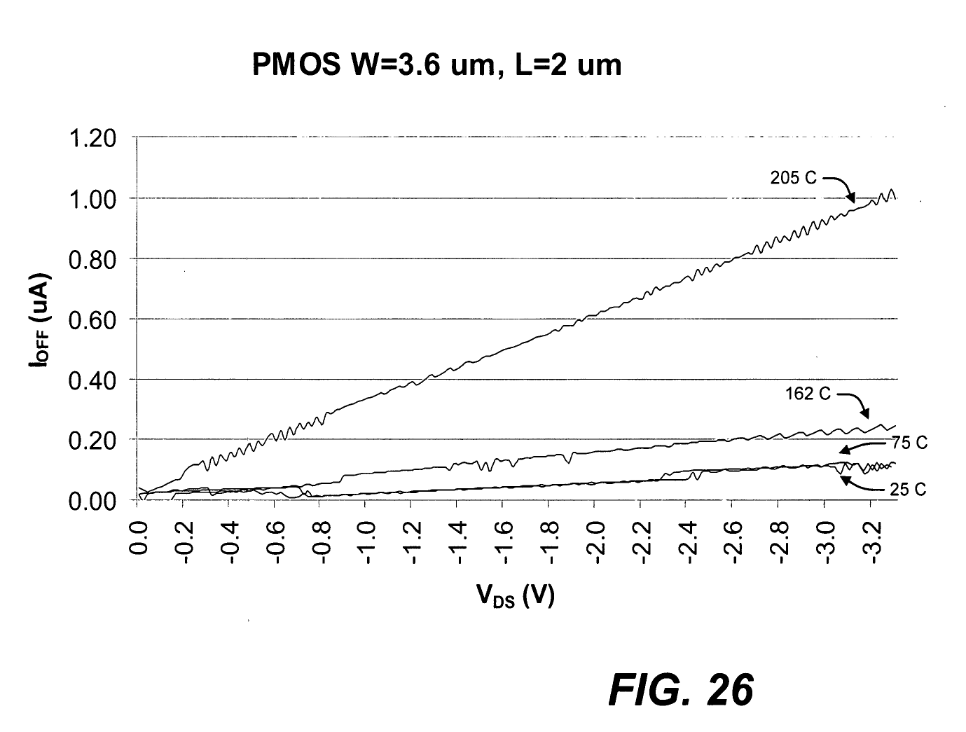

The effects of changing the dimensions of PMOS and NMOS transistors on their leakage current versus temperature are shown in FIGS. 26-33.

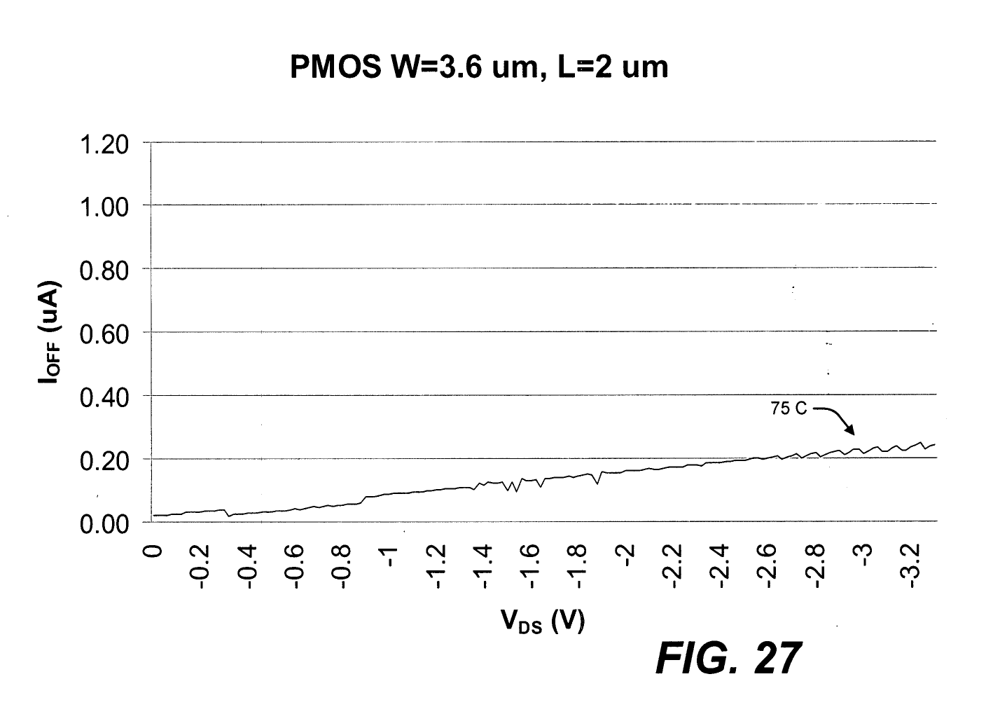

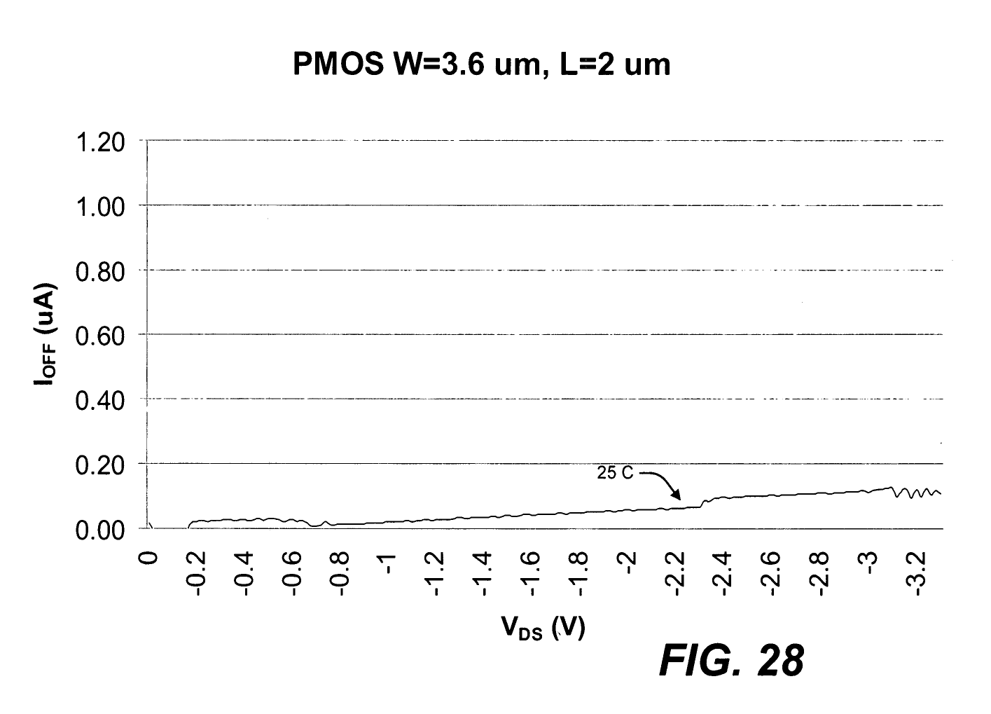

FIGS. 26-30 are plots of leakage current (I_{OFF}) (in micro-Amperes) versus drain-to-source voltage (V_{DS}) (in Volts) in Positive-Channel Metal Oxide Semiconductor (PMOS) transistors at different temperatures. These plots may be referred to as I-V curves. FIGS. 26-28 shows a series of I-V curves for a PMOS transistor with a width of 3.6 μm and a length of 2 μm that was fabricated using an SOS process. I-V curves are plotted for the example PMOS transistor at 25° C., 75° C., 162° C., and 205° C. are shown. The I-V curves for the 75° C. and 25° C. plots are shown alone in FIGS. 27 and 28, respectively, for differentiation between the two curves.

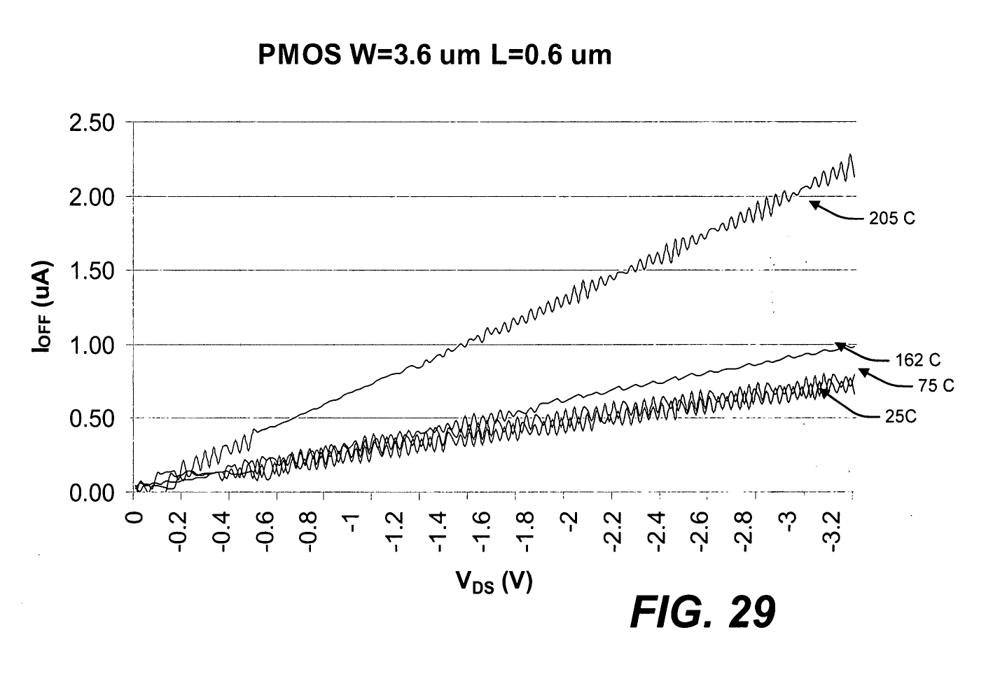

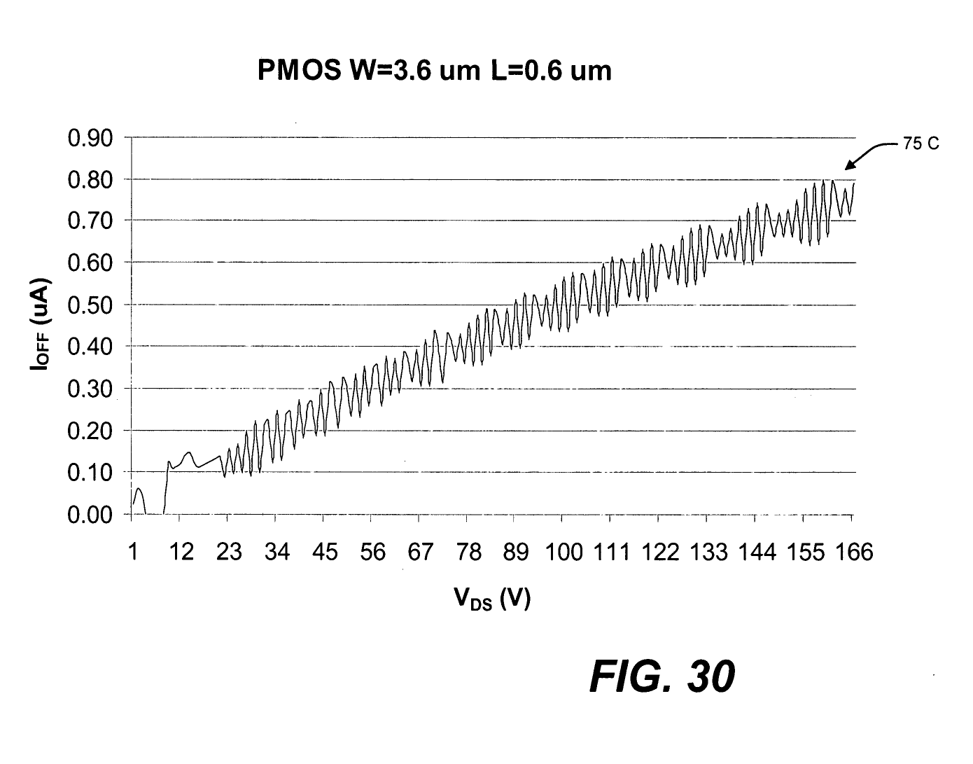

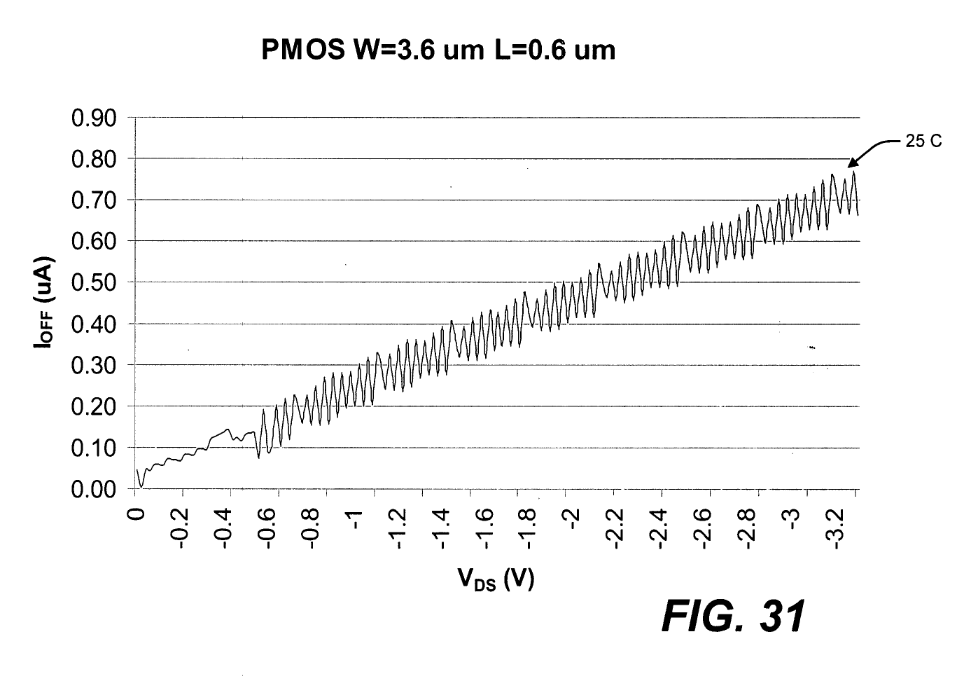

FIGS. 29-31 are I-V curves for a PMOS transistor with a width of 3.6 μm and a length of 0.6 μm that was fabricated using a SOS process. The I-V curves show the leakage current (I_{OFF}) (in micro-Amperes) versus drain-to-source voltage (V_{DS}) (in Volts) for the PMOS transistor at 25° C., 75° C., 162° C., and 205° C. The curves for 75° C. and 25° C. are shown alone in FIGS. 30 and 31, respectively, for differentiation.

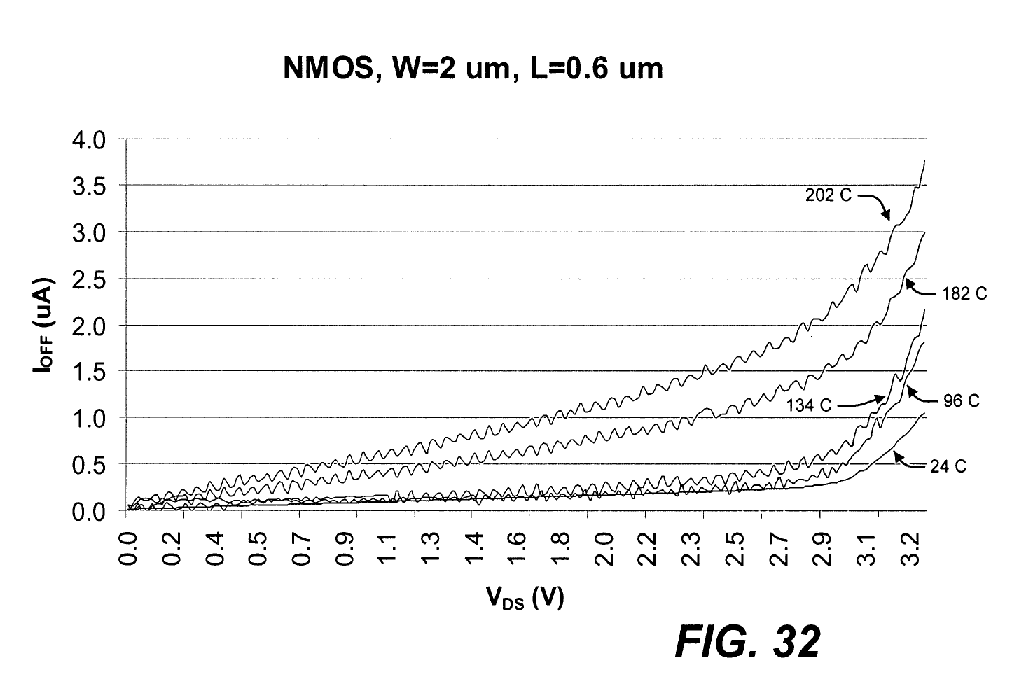

FIG. 32 shows a series of I-V curves for a Negative-Channel Metal Oxide Semiconductor (NMOS) transistor. The NMOS transistor has a width of 2 μm and a length of 0.6 μm. The I-V curve shows the leakage current (I_{OFF}) (in micro-Amperes) versus drain-to-source voltage (V_{DS}) (in Volts) for the NMOS transistor at 24° C., 96° C., 134° C., 182° C., and 202° C.

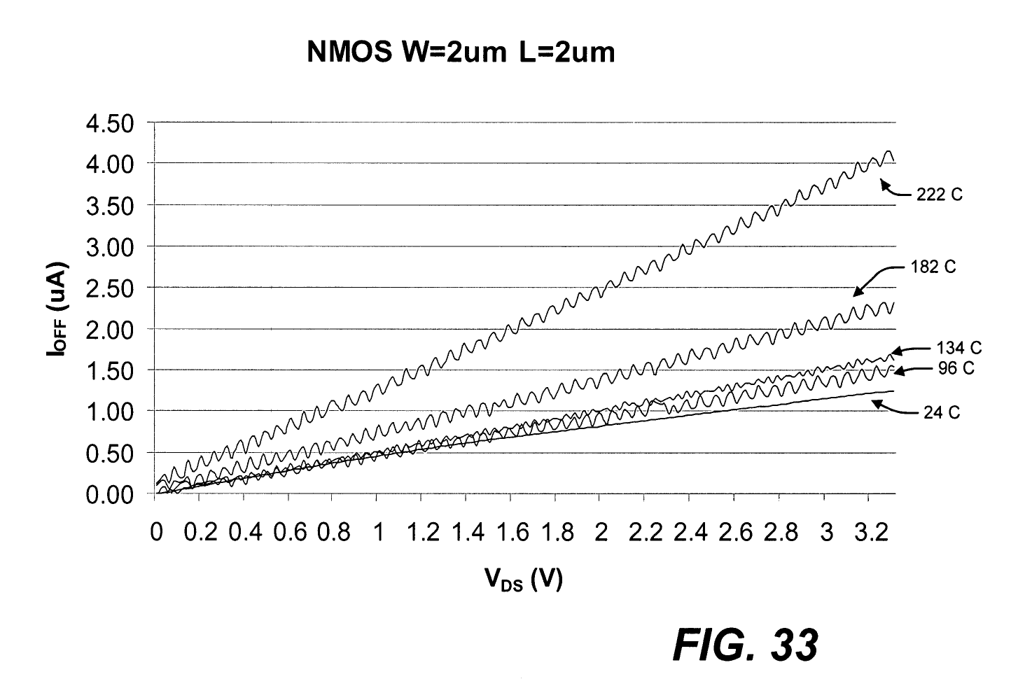

FIG. 33 shows a series of I-V curves for a Negative-Channel Metal Oxide Semiconductor (NMOS) transistor (as in FIG. 21). The NMOS transistor has a width of 2 μm and a length of 2 μm. The I-V curve shows the leakage current (I_{OFF}) (in micro-Amperes) versus drain-to-source voltage (V_{DS}) (in Volts) for the NMOS transistor at 24° C., 96° C., 134° C., 182° C., and 222° C.

The characteristics of the NMOS and PMOS transistors shown in FIGS. 26-33 may be considered when designing memory controller 110. For example, the temperature-dependant characteristics of the NMOS and PMOS transistors may be considered when determining the lengths and widths of one or more ports of the active layer in the transistors in the memory controller 110. In another example, the temperature-dependant characteristic of the NMOS and PMOS transistors may be considered when determining whether to use PMOS- or NMOS- logic for portions of the memory controller 110.

One parameter that may be varied during device fabrication is the length of the active layer of the transistors. In one example, beta noise matching may be used to determine the lengths of the active layers of the transistors. The beta matched approach may be used to develop a high speed transistor optimized for a high temperature (e.g., 300° C.). In one example design, optimal noise characteristics may be maintained by choosing a higher leakage current over a higher speed performance. In one implementation, the following equation may be used to beta match a device:

$$\frac{{W}_{p}}{{L}_{p} } = KR \frac{{W}_{N}}{{L}_{N}} ,$$

where W is the width and L is the length of the active layer of the semiconductor devices, W/L is the width to length ratio of the active layer of the semiconductor device, and KR is the ratio of mobility electrons to mobility holes. In one example, KR may range from 1.5 to 3. Further, the mobility and leakage current of an NMOS device may be higher for a given gate length L than that of a PMOS device. Selecting a PMOS device having a gate length Lp and an NMOS device having a gate length Ln to minimize leakage current and maximize speed of the device, and selecting KR at a given temperature to determine the desired Wp to Wn ratio may result in a device having optimal leakage performance or having optimal leakage current versus device speed. In one example, if KR=1.5, Lₚ=0.8 μm, Wₚ=Wₙ, Lₙ may be selected to be 1.2 μm. In another example, if KR=2, Lₚ=0.8 μm, Wₚ/Wₙ=1.6, Ln may be selected to be 1.2 um.

In other example system, beta matching may be used to equalize the turn-on or turn-off time of the PMOS and NMOS transistors in the memory system 100. In one example system, the transistors may be beta-matched for equal turn-on or turn-off times at a predetermined temperature, such as 180° C., 240° C., or 300° C.

The memory system 100 may be used in a high-temperature or radioactive environments. Such environments may include well-drilling, power generation, space applications, environments within or near a jet engine, or environments within or near an internal-combustion engine. The term well-drilling is not meant to be limited to oil-well drilling and may include any applications subject to a high temperature downhole environment, such as logging applications, workover applications, long term production monitoring applications, downhole controls, fluid extraction applications, measurement or logging while drilling applications.

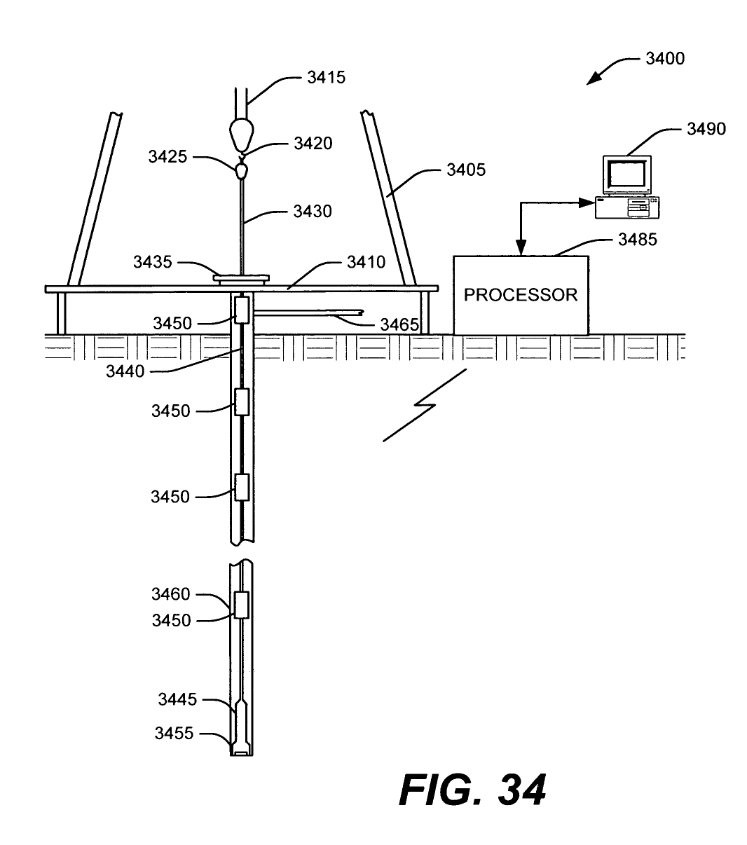

Memory systems 100 may be used in one or more oil-well drilling systems. As shown in FIG. 34, oil well drilling equipment 3400 (simplified for ease of understanding) includes a derrick 3405, derrick floor 3410, draw works 3415 (schematically represented by the drilling line and the traveling block), hook 3420, swivel 3425, kelly joint 3430, rotary table 3435, drillpipe 3440, drill collar 3445, subs 3450, and drill bit 3455. Drilling fluid, such as mud, foam, or air, is injected into the swivel by a drilling fluid supply line (not shown). The drilling fluid travels through the kelly joint 3430, drillpipe 3440, drill collars 3445, and LWD/MWD tools 3450, and exits through jets or nozzles in the drill bit 3455. The drilling fluid then flows up the annulus between the drill pipe 3440 and the wall of the borehole 3460. A drilling fluid return line 3465 returns drilling fluid from the borehole 3460 and circulates it to a drilling fluid pit (not shown) and back to the drilling fluid supply line (not shown). The combination of the drill collar 3445 and drill bit 3455 is known as the bottomhole assembly (or “BHA”). The combination of the BHA and the drillpipe 3440 is known as the drillstring. In rotary drilling the rotary table 3435 may provide rotation to the drill string, or alternatively the drill string may be rotated via a top drive assembly. The term “couple” or “couples” used herein is intended to mean either an indirect or direct connection. Thus, if a first device couples to a second device, that connection may be through a direct connection, or through one or more intermediate devices.

The downhole equipment may be in communication with a processor 3485, which may in turn be in communication with a terminal 3490. One or more MRAM arrays 100 may be used in portion of the oil well drilling equipment 3400. In one example system, the memory system may be included in the drill collars 3445, the drill bit 3455, one or more of the subs 3450, or other portions of the oil well drilling equipment. In another example system, the memory may be disposed in casing that is used to case the borehole 3460 and left downhole.

It will be understood that the term “oil well drilling equipment” or “oil well drilling system” is not intended to limit the use of the equipment and processes described with those terms to drilling an oil well. The terms also encompass drilling natural gas wells or hydrocarbon wells in general. Further, such wells can be used for production, monitoring, or injection in relation to the recovery of hydrocarbons or other materials from the subsurface. As used herein, “oil well drilling equipment” also includes fracturing, workover, and other downhole equipment.

Therefore, the present invention is well-adapted to carry out the objects and attain the ends and advantages mentioned as well as those which are inherent therein. While the invention has been depicted, described, and is defined by reference to exemplary embodiments of the invention, such a reference does not imply a limitation on the invention, and no such limitation is to be inferred. The invention is capable of considerable modification, alternation, and equivalents in form and function, as will occur to those ordinarily skilled in the pertinent arts and having the benefit of this disclosure. For example, the MRAM of the present invention may replace many memory devices, including ROM, flash memory, RAM, SRAM, and DRAM. Furthermore, the MRAM of the present invention may also replace computer disk drives. The depicted and described embodiments of the invention are exemplary only, and are not exhaustive of the scope of the invention. Consequently, the invention is intended to be limited only by the spirit and scope of the appended claims, giving full cognizance to equivalents in all respects.

1. A memory system for storing one or more bits, comprising:
a substrate comprising sapphire;
a magnetic random access memory (MRAM) array disposed on the substrate; and
a memory controller disposed on the substrate and in communication with the MRAM array.

2. The memory system of claim 1, where the memory controller comprises:
one or more semiconductor devices, where one or more of the semiconductor devices comprise:
an active layer having a thickness tSi and comprising a channel region, the channel region having a length L, where L/tSi is above 7; and
an oxide layer disposed on the active layer.

3. The memory system of claim 1, where the one or more semiconductor devices comprise:
one or more P-channel transistors.

4. The memory system of claim 1, where the one or more semiconductor devices comprise:
one or more N-channel transistors.

5. The memory system of claim 1, where L/tSi is between 11.8 and 25.

6. The memory system of claim 1, where L/tSi is about 17.7.

7. The memory system of claim 1, where the memory controller comprises:
one or more P-channel transistors
one or more N-channel transistors; and one or more of the transistors comprising:
an active layer having a thickness tSi disposed on the substrate, the active layer comprising a semiconductor with two or more doped regions, the doped regions comprising a channel region having a length L;
an oxide layer disposed on the active layer, the oxide layer comprising an insulator and having a thickness TOX;
a geometry defined by two or more of tSi, TOX, and L; and
the geometry, the semiconductor of the active layer, and the oxide of the second layer having been selected to limit a ratio I_{ON}/I_{OFF} to more than 100 at temperatures up to 125° C., where I_{OFF} is a leakage current flowing through the substrate and I_{ON} is a current flowing through the active layer.

8. The memory system of claim 7, where the geometry, the semiconductor of the active layer, and the oxide of the second layer have further been selected to limit a ratio I_{ON}/I_{OFF} to more than 1000 at temperatures up to 125° C.

9. The memory system of claim 1, where the memory controller comprises:
one or more P-channel transistors;
one or more N-channel transistors; and one or more of the transistors comprising:
an active layer having a thickness tSi disposed on the substrate, the active layer comprising a semiconductor with two or more doped regions, the doped regions comprising a channel region having a length L;
an oxide layer disposed on the active layer, the oxide layer comprising an insulator and having a thickness TOX;
a geometry defined by two or more of tSi, TOX, and L; and
the geometry, the semiconductor of the active layer, and the oxide of the second layer having been selected to limit a ratio I_{ON}/I_{OFF} to more than 100 at temperatures up to 240° C., where I_{OFF} is a leakage current flowing through the substrate and I_{ON} is a current flowing through the active layer.

10. The memory system of claim 9, where the geometry, the semiconductor of the active layer, and the oxide of the second layer have further been selected to limit a ratio I_{ON}/I_{OFF} to more than 1000 at temperatures up to 240° C.

11. The memory system of claim 1, where the memory controller comprises:
one or more P-channel transistors comprising a first portion of the substrate, where the P-channel semiconductor device is characterized by a gain βₚ and a leakage current I_{OFF-P};
one or more N-channel transistors in communication with the one or more P-channel transistors, the N-channel transistors comprising a second portion of the substrate, where each N-channel transistor is characterized by a gain βₙ and a leakage current I_{OFF-N}; and
where, at a predetermined temperature:
βₚ~βₙ; and
I_{OFF-P}~I_{OFF-N}.

12. The memory system of claim 11, where the predetermined temperature is between 125° C. and 300° C.

13. The memory system of claim 11, where one or more of the P-channel transistors are connected in parallel with one or more of the N-channel transistors.

14. The memory system of claim 11, where one or more of the P-channel transistors are connected in series with one or more of the N-channel transistors.

15. The memory system of claim 11, where:
each of the P-channel transistors comprise an active layer that is disposed on the substrate, the active layer comprising a channel region with a length L_{P} and a width W_{P}; and
each of the N-channel transistors comprise an active layer that is disposed on the substrate, the active layer comprising a channel region with a length L_{N} and a width W_{N}; and
where, at the predetermined temperature:
$$\frac{{W}_{p}}{{L}_{p} } = KR \frac{{W}_{N}}{{L}_{N}} ,$$
where KR is a ratio of an electron mobility to a hole mobility at the predetermined temperature.

16. The memory system of claim 15 where the active layer has a thickness tSi and where L_{P}/tSi is between 7 and 30.

17. The memory system of claim 15 where the active layer has a thickness tSi and where L_{P}/tSi is between 11.8 and 25.

18. The memory system of claim 15 where the active layer has a thickness tSi and where L_{P}/tSi is about 17.7.

19. The memory system of claim 15 where the active layer has a thickness tSi and where L_{N}/tSi is between 7 and 30.

20. The memory system of claim 15 where the active layer has a thickness tSi and where L_{N}/tSi is between 11.8 and 25.

21. The memory system of claim 15 where the active layer has a thickness tSi and where L_{N}/tSi is about 17.7.

22. The memory system of claim 1, where the memory controller comprises:
one or more P-channel transistors comprising a first portion of the substrate, where each P-channel transistor is characterized by a gain βₚ and a switching time tₛ₋ₚ for an output of the P-channel transistor to change in response to a change in an input to the P-channel transistor;
one or more N-channel transistors in communication with the one or more of the P-channel transistors, the N-channel transistors comprising a second portion of the substrate, where each N-channel transistor is characterized by a gain βₙ, and a switching time tₛ₋ₙ for an output of the N-channel transistor to change in response to a change in an input to the N-channel transistor, and
where, at a predetermined temperature:
βₚ~βₙ; and
tₛ₋ₚ~tₛ₋ₙ.

23. The memory system of claim 22, where tₛ₋ₚ and tₛ₋ₙ are turn-on times and where the predetermined temperature is up to 300° C.

24. The memory system of claim 22, where tₛ₋ₚ and tₛ₋ₙ are turn-off times and where the predetermined temperature is up to 300° C.

25. The memory system of claim 22, where one or more of the P-channel transistors are connected in parallel with one or more of the N-channel transistors.

26. The memory system of claim 22, where one or more of the P-channel transistors are connected in series with one or more of the N-channel transistors.

27. The memory system of claim 1, where the MRAM array comprises:
one or more word lines;
one or more sense lines; and
one or more spots, where each spot is traversed by a word line and a sense line.

28. The memory system of claim 27, where each spot is to store a magnetic charge.

29. The memory system of claim 28, where the magnetic charge is to alter a resistance to a sense signal applied to the sense line traversing the spot.

30. The memory system of claim 27, where the MRAM array comprises:
one or more cells comprising:
one or more spots traversed by a first sense line.

31. The memory system of claim 30, where the cell is to store a bit.

32. The memory system of claim 30, where the memory controller comprises:
one or more word line drivers to apply a word line signal to one or more word lines; and
where the word line driver is to apply the same word line signal to each of the one or more spots in the cell.

33. The memory system of claim 27, where the MRAM array comprises:
one or more cells comprising:
a K set of one or more spots traversed by a first sense line;
a K-bar set of one or more spots traversed by a second sense line.

34. The memory system of claim 33, where the cell is to store a bit.

35. The memory system of claim 33 where:
the K set of spots are each to store a first magnetic charge;
the K-bar set of spots are each to store a second magnetic charge; and
the first magnetic charge is complementary to the second magnetic charge.

36. The memory system of claim 33, the memory controller further comprising:
a sense amplifier to read one or more bits where, when the sense amplifier is determining a bit state:
the sense amplifier measures a voltage difference between the K set of spots and the K-bar set of spots for a cell.

37. The memory system of claim 33, where the memory controller comprises:
one or more word line drivers to apply a word line signal to one or more word lines; and where:
one or more word line drivers apply a first word line signal to the K set of spots to set them to a first state;
one or more word line drivers apply a second word line signal to each of the spots in the K-bar set of spots to set them to a second state; and where
the first state and the second state are opposite.

38. The memory system of claim 37, where:
the one or more word line drivers apply the first word line signal to the K set of spots and apply the second word line signal to the K-bar set of spots substantially simultaneously.

39. The memory system of claim 37, where:
the one or more word line drivers apply the first word line signal to the K set of spots and apply the second word line signal to the K-bar set of spots sequentially.

40. The memory system of claim 1, where the memory controller comprises:
one or more word line drivers, each to apply a word line signal to one or more word lines in the MRAM array;
one or more sense line drivers, each to apply a sense line signal to one or more sense lines in the MRAM array.

41. The memory system of claim 40, where the memory controller further comprises:
an addressing system to receive an address and operate one or more of the word line drivers and one or more of the sense line drivers based on the received address.

42. The memory system of claim 1, where the memory system is for use in one or more of the following environments:
in a power-generation environment;
in a well-drilling environment;
in space;
within or near a jet engine; or
within or near an internal-combustion engine.

43. A memory system for storing one or more bits, including:
a substrate comprising sapphire;
a magnetic random access memory (MRAM) array disposed on the substrate; and
a memory controller disposed on the substrate and in communication with the MRAM array.

44. The memory system of claim 43, where the memory controller comprises:
one or more semiconductor devices, where one or more of the semiconductor devices comprise:
an active layer having a thickness tSi and comprising a channel region with a length L, where L/tSi is between 7 and 30; and
an oxide layer disposed on the active layer.

45. The memory system of claim 43, where the one or more semiconductor devices comprise:
one or more P-channel transistors.

46. The memory system of claim 43, where the one or more semiconductor devices comprise:
one or more N-channel transistors.

47. The memory system of claim 44, where L/tSi is between 11.8 and 25.

48. The memory system of claim 44, where L/tSi is about 17.7.

49. The memory system of claim 43, where the memory controller comprises:
one or more P-channel transistors;
one or more N-channel transistors; and one or more of the transistors comprising:
an active layer disposed on the substrate, the active layer comprising a semiconductor with two or more doped regions and having a length L and a thickness tSi;
an oxide layer disposed on the active layer, the oxide layer comprising an insulator and having a thickness TOX;
a geometry defined by two or more of tSi, TOX, and L; and
the geometry, the semiconductor of the active layer, and the oxide of the second layer having been selected to limit a ratio I_{ON}/I_{OFF} to more than 100 at temperatures up to 125° C., where I_{OFF} is a leakage current flowing through the substrate and I_{ON} is a current flowing through the active layer.

50. The memory system of claim 49, where the geometry, the semiconductor of the active layer, and the oxide of the second layer have further been selected to limit a ratio I_{ON}/I_{OFF} to more than 1000 at temperatures up to 125° C.

51. The memory system of claim 43, where the memory controller comprises:
one or more P-channel transistors;
one or more N-channel transistors; and one or more of the transistors comprising:
an active layer disposed on the substrate, the active layer having a thickness tSi and comprising a semiconductor with two or more doped regions including a channel region having a length L;
an oxide layer disposed on the active layer, the oxide layer comprising an insulator and having a thickness TOX;
a geometry defined by two or more of tSi, TOX, and L; and
the geometry, the semiconductor of the active layer, and the oxide of the second layer having been selected to limit a ratio I_{ON}/I_{OFF} to more than 100 at temperatures up to 240° C., where I_{OFF} is a leakage current flowing through the substrate and I_{ON} is a current flowing through the active layer.

52. The memory system of claim 51, where the geometry, the semiconductor of the active layer, and the oxide of the second layer have further been selected to limit a ratio I_{ON}/I_{OFF} to more than 1000 at temperatures up to 240° C.

53. The memory system of claim 43, where the memory controller comprises:
one or more P-channel transistors comprising a first portion of the substrate, where the P-channel semiconductor device is characterized by a gain βₚ and a leakage current I_{OFF-P};
one or more N-channel transistors in communication with the one or more P-channel transistors, the N-channel transistors comprising a second portion of the substrate, where each N-channel transistor is characterized by a gain βₙ and a leakage current I_{OFF-N}; and
where, at a predetermined temperature:
βₚ~βₙ; and
I_{OFF-P}~I_{OFF-N}.

54. The memory system of claim 53, where the predetermined temperature is between 125° C. and 300° C.

55. The memory system of claim 53, where one or more of the P-channel transistors are connected in parallel with one or more of the N-channel transistors.

56. The memory system of claim 53, where one or more of the P-channel transistors are connected in series with one or more of the N-channel transistors.

57. The memory system of claim 53, where:
each of the P-channel transistors comprise an active layer that is disposed on the substrate and comprises a channel region having a length L_{P} and a width W_{P}; and
each of the N-channel transistors comprise an active layer that is disposed on the substrate and comprises a channel region having a length L_{N} and a width W_{N}; and
where, at the predetermined temperature:
$$\frac{{W}_{p}}{{L}_{p} } = KR \frac{{W}_{N}}{{L}_{N}} ,$$
where KR is a ratio of an electron mobility to a hole mobility at the predetermined temperature.

58. The memory system of claim 57 where the active layer has a thickness tSi and where L_{P}/tSi is between 7 and 30.

59. The memory system of claim 57 where the active layer has a thickness tSi and where L_{P}/tSi is between 11.8 and 25.

60. The memory system of claim 57 where the active layer has a thickness tSi and where L_{P}/tSi is about 17.7.

61. The memory system of claim 43, where the memory controller comprises:
one or more P-channel transistors comprising a first portion of the substrate, where each P-channel transistor is characterized by a gain βₚ and a switching time tₛ₋ₚ for an output of the P-channel transistor to change in response to a change in an input to the P-channel transistor;
one or more N-channel transistors in communication with the one or more of the P-channel transistors, the N-channel transistors comprising a second portion of the substrate, where each N-channel transistor is characterized by a gain βₙ, and a switching time tₛ₋ₙ for an output of the N-channel transistor to change in response to a change in an input to the N-channel transistor, and
where, at a predetermined temperature:
βₚ~βₙ; and
t_{s-p~t}ₛ₋ₙ.

62. The memory system of claim 61, where tₛ₋ₚ and tₛ₋ₙ are turn-on times and where the predetermined temperature is between 125° C. and 300° C.

63. The memory system of claim 61, where tₛ₋ₚ and tₛ₋ₙ are turn-off times and where the predetermined temperature is between 125° C. and 300° C.

64. The memory system of claim 61, where one or more of the P-channel transistors are connected in parallel with one or more of the N-channel transistors.

65. The memory system of claim 61, where one or more of the P-channel transistors are connected in series with one or more of the N-channel transistors.

66. The memory system of claim 43, where the MRAM array comprises:
one or more word lines;
one or more sense lines; and
one or more spots, where each spot is traversed by a word line and a sense line.

67. The memory system of claim 66, where each spot is to store a magnetic charge.

68. The memory system of claim 67, where the magnetic charge is to alter a resistance to a sense signal applied to the sense line traversing the spot.

69. The memory system of claim 66, where the MRAM array comprises:
one or more cells comprising:
one or more spots traversed by a first sense line.

70. The memory system of claim 69, where the cell is to store a bit.

71. The memory system of claim 69, where the memory controller comprises:
one or more word line drivers to apply a word line signal to one or more word lines; and
where the word line driver is to apply the same word line signal to each of the one or more spots in the cell.

72. The memory system of claim 69, where the MRAM array comprises:
one or more cells comprising:
a K set of one or more spots traversed by a first sense line;
a K-bar set of one or more spots traversed by a second sense line.

73. The memory system of claim 72, where the cell is to store a bit.

74. The memory system of claim 72 where:
the K set of spots are each to store a first magnetic charge;
the K-bar set of spots are each to store a second magnetic charge; and
the first magnetic charge is complementary to the second magnetic charge.

75. The memory system of claim 72, the memory controller further comprising:
a sense amplifier to read one or more bits where, when the sense amplifier is determining a bit state:
the sense amplifier measures a voltage difference between the K set of spots and the K-bar set of spots for a cell.

76. The memory system of claim 72, where the memory controller comprises:
one or more word line drivers to apply a word line signal to one or more word lines; and
where:
one or more word line drivers apply a first word line signal to the K set of spots to set them to a first state;
one or more word line drivers apply a second word line signal to each of the spots in the K-bar set of spots to set them to a second state; and where
the first state and the second state are opposite.

77. The memory system of claim 76, where:
the one or more word line drivers apply the first word line signal to the K set of spots and apply the second word line signal to the K-bar set of spots substantially simultaneously.

78. The memory system of claim 76, where:
the one or more word line drivers apply the first word line signal to the K set of spots and apply the second word line signal to the K-bar set of spots sequentially.

79. The memory system of claim 43, where the memory controller comprises:
one or more word line drivers, each to apply a word line signal to one or more word lines in the MRAM array;
one or more sense line drivers, each to apply a sense line signal to one or more sense lines in the MRAM array.

80. The memory system of claim 79, where the memory controller further comprises:
an addressing system to receive an address and operate one or more of the word line drivers and one or more of the sense line drivers based on the received address.

81. The memory system of claim 43, where the memory system is for use in one or more of the following environments:
in a power-generation environment;
in a well-drilling environment;
in space;
within or near a jet engine; or
within or near an internal-combustion engine.

82. A memory system for storing one or more bits, including:
a magnetic random access memory (MRAM) array comprising:
one or more word lines;
one or more sense lines;
one or more cells, each to store a bit, where one or more cells comprise:
two or more spots, where each spot is traversed by a word line and a sense line, and where each spot in the cell is traversed by a common sense line; and
a memory controller in communication with the MRAM array.

83. The memory system of claim 82, where the two or more spots in the cell are adjacent on the common sense line.

84. The memory system of claim 82, where the memory controller comprises:
one or more word line drivers to apply a word line signal to one or more word lines; and
where the word line driver is to apply the same word line signal to each of the two or more spots in one or more of the cells.

85. A memory system for storing one or more bits, including:
a magnetic random access memory (MRAM) array comprising:
one or more word lines;
one or more sense lines;
one or more cells, each to store a bit, where one or more cells comprise:
one or more spot sets, where each spot is traversed by a word line and a sense line, and where each spot in the spot set is traversed by a common sense line; and
a memory controller in communication with the MRAM array, where the memory controller includes a leakage compensation system.

86. The memory system of claim 85, where the leakage compensation system comprises:
for one or more sense lines:
a buffer comprising an input and an output, where the output is connected to an end of the sense line, and where the buffer is characterized by a gain; and
for each cell traversed by the sense line: a shoring switch to short the cell to the input of the buffer.

87. The memory system of claim 86, where the buffer is characterized by a unity gain.

88. The memory system of claim 86, where when the cell is not being read from or written to, the shorting switch is closed.

89. The memory system of claim 88, where each cell comprises a K spot set and a K-bar spot set, and where the leakage compensation system comprises:
for the pair of sense lines for the K spot set and the K-bar spot set:
a amplifier comprising an inverting input, a non-inverting input, and an output, where the output is connected to ends of the pair of sense lines;
a model circuit connected to the non-inverting input of the amplifier, where the model circuit is to model a cell with substantially no leakage current;
a resistor divider comprising two or more resistors, and having a midpoint and ends for the K spot set and the K-bar spot set, where the midpoint is connected with the inverting input of the amplifier; and
for each cell traversed by the sense line:
a switch to short the cell to the resistor divider.

90. The memory system of claim 88, where when the cell is not being read from or written to, the switch is closed.

91. A method of fabricating a memory system, comprising:
fabricating an MRAM array on a substrate, where the substrate comprises sapphire; and
fabricating a memory controller on the substrate.

92. The method of claim 94, including:
planarizing the MRAM array.

93. The method of claim 95, where planarizing the MRAM array on the substrate includes:
performing chemical machine polishing.

94. The method of claim 95, where planarizing the MRAM array is performed before fabricating the memory controller.

95. The method of claim 94, where fabricating electronic circuitry on the substrate comprises:
forming an active layer on the substrate;
fabricating one or more semiconductor devices in the active layer.

96. The method of claim 95, where forming the active layer on the substrate comprises:
forming a thin-film active layer on the substrate.

97. The method of claim 96, where forming the thin-film active layer on the substrate comprises:
growing a active layer on the substrate;
implanting ionic silicon on the silicon layer;
annealing the silicon layer;
oxidizing the silicon layer, to create an oxide layer; and
stripping the oxide layer.

98. The method of claim 97, where growing a active layer on the substrate comprises:
depositing silicon on the substrate using chemical vapor deposition.

99. The method of claim 98, where annealing the active layer comprising:
inducing solid phase epitaxial regrowth; and
removing defects from the silicon layer.

100. The method of claim 96, where fabricating one or more semiconductor devices in the active layer comprises:
doping one or more active layer regions to create N regions;
doping one or more active layer regions to create P regions;
applying a planarization resist;
etching to expose one or more gate tops;
etching contact holes; and
depositing a metal layer.

101. The method of claim 95, where fabricating one or more semiconductor devices in the active layer comprises:
fabricating one or more N-channel transistors.

102. The method of claim 95, where fabricating one or more semiconductor devices in the active layer comprises:
fabricating one or more P-channel transistors.

103. The method of claim 95, where the active layer has a thickness tSi and comprises a channel region with a length L, and where forming the active layer on the substrate comprises:
controlling the formation of the active layer to cause L/tSi to be between 7 and 30.

104. The method of claim 95, where the active layer has a thickness tSi and comprises a channel region with a length L, and where forming the active layer on the substrate comprises:
controlling the formation of the active layer to cause L/tSi to be between 11.8 and 25.

105. The method of claim 95, where the active layer has a thickness tSi and comprises a channel region with a length L, and where forming the active layer on the substrate comprises:
controlling the formation of the active layer to cause L/tSi to be about 17.7.

106. The method of claim 95, further comprising:
depositing an oxide layer on the active layer.

107. The method of claim 91, where the memory system is for use in one or more of the following environments:
in a power-generation environment;
in a well-drilling environment;
in space;
within or near a jet engine; or
within or near an internal-combustion engine.

108. A method of fabricating a memory system, comprising:
fabricating an MRAM array on a substrate, where the substrate comprises diamond; and
fabricating a memory controller on the substrate.

109. The method of claim 108, including:
planarizing the MRAM array.

110. The method of claim 109, where planarizing the MRAM array on the substrate includes:
performing chemical machine polishing.

111. The method of claim 109, where planarizing the MRAM array is performed before fabricating the memory controller.

112. The method of claim 108, where fabricating electronic circuitry on the substrate comprises:
forming an active layer on the substrate;
fabricating one or more semiconductor devices in the active layer.

113. The method of claim 112, where forming the active layer on the substrate comprises:
forming a thin-film active layer on the substrate.

114. The method of claim 113, where forming the thin-film active layer on the substrate comprises:
growing a active layer on the substrate;
implanting ionic silicon on the silicon layer;
annealing the silicon layer;
oxidizing the silicon layer, to create an oxide layer; and
stripping a portion the oxide layer.

115. The method of claim 114, where growing a active layer on the substrate comprises:
depositing silicon on the substrate using chemical vapor deposition.

116. The method of claim 115, where annealing the active layer comprising:
inducing solid phase epitaxial regrowth; and
removing defects from the silicon layer.

117. The method of claim 113, where fabricating one or more semiconductor devices in the active layer comprises:
doping one or more active layer regions to create N regions;
doping one or more active layer regions to create P regions;
applying a planarization resist;
etching to expose one or more gate tops;
etching contact holes; and
depositing a metal layer.

118. The method of claim 112, where fabricating one or more semiconductor devices in the active layer comprises:
fabricating one or more N-channel transistors.

119. The method of claim 112, where fabricating one or more semiconductor devices in the active layer comprises:
fabricating one or more P-channel transistors.

120. The method of claim 112, where the active layer has a thickness tSi and where forming the active layer on the substrate comprises:
creating a channel region in the active layer, where the channel region has a length L; and
controlling the formation of the active layer to cause L/tSi to be between 7 and 30.

121. The method of claim 112, where the active layer has a thickness tSi and where forming the active layer on the substrate comprises:
creating a channel region in the active layer, where the channel region has a length L; and
controlling the formation of the active layer to cause L/tSi to be between 11.8 and 25.

122. The method of claim 112, where the active layer has a thickness tSi and where forming the active layer on the substrate comprises:
creating a channel region in the active layer, where the channel region has a length L; and
controlling the formation of the active layer to cause L/tSi to be about 17.7.

123. The method of claim 112, further comprising:
depositing an oxide layer on the active layer.

124. The method of claim 108, where the memory system is for use in one or more of the following environments:
in a power-generation environment;
in a well-drilling environment;
in space;
within or near a jet engine; or
within or near an internal-combustion engine.

125. A system for use in an oil well, comprising:
a memory system capable of operating at an elevated temperature, comprising:
a substrate comprising sapphire and having a thickness tSi;
a magnetic random access memory (MRAM) array disposed on the substrate; and
a memory controller disposed on the substrate and in communication with the MRAM array.

126. The system of claim 125, where the memory controller comprises:
one or more transistors, where one or more of the transistors comprise:
an active layer comprising a channel region with a length L, where L/tSi is greater than 7.

127. The system of claim 125, where the memory controller comprises:
one or more transistors, where one or more of the transistors comprise:
an active layer comprising a channel region with a length L, where L/tSi is between 7 and 30.

128. The system of claim 125, where the memory controller comprises:
one or more transistors, where one or more of the transistors comprise:
an active layer comprising a channel region with a length L, where L/tSi is between 11.8 and 25.

129. The system of claim 125, where the memory controller comprises:
one or more transistors, where one or more of the transistors comprise:
an active layer comprising a channel region with a length L, where L/tSi is about 17.7.

130. The system of claim 125, where the memory system is to be left downhole after drilling.

131. A system for use in an oil well, comprising:
a memory system capable of operating at an elevated temperature, comprising:
a substrate comprising sapphire and having a thickness tSi;
a magnetic random access memory (MRAM) array disposed on the substrate; and
a memory controller disposed on the substrate and in communication with the MRAM array.

132. The system of claim 131, where the memory controller comprises:
one or more transistors, where one or more of the transistors comprise:
an active layer comprising a channel region with a length L, where L/tSi is greater than 7.

133. The system of claim 131, where the memory controller comprises:
one or more transistors, where one or more of the transistors comprise:
an active layer comprising a channel region with a length L, where L/tSi is between 7 and 30.

134. The system of claim 131, where the memory controller comprises:
one or more transistors, where one or more of the transistors comprise:
an active layer comprising a channel region with a length L, where L/tSi is between 11.8 and 25.

135. The system of claim 131, where the memory controller comprises:
one or more transistors, where one or more of the transistors comprise:
an active layer comprising a channel region with a length L, where L/tSi is about 17.7.

136. The system of claim 131, where the memory system is to be left downhole after drilling.
